(19) United States
(12) Patent Application Publication
(10) Pub. No.: US 2015/0129865 A1
(43) Pub. Date: May 14, 2015

(54) SEMICONDUCTOR DEVICE AND METHOD FOR MANUFACTURING SAME

(71) Applicant: Sharp Kabushiki Kaisha, Osaka-shi, Osaka (JP)

(72) Inventors: Tadayoshi Miyamoto, Osaka-shi (JP); Kazuatsu Ito, Osaka-shi (JP); Mitsunobu Miyamoto, Osaka-shi (JP); Yutaka Takamaru, Osaka-shi (JP)

(21) Appl. No.: 14/384,468

(22) PCT Filed: Mar. 4, 2013
(86) PCT No.: PCT/JP2013/055856

§ 371 Date: Sep. 11, 2014

(30) Foreign Application Priority Data
Mar. 12, 2012 (JP) 2012-054169

(51) Int. Cl. H01L 29/786; H01L 21/44; H01L 21/027; H01L 21/02; H01L 29/45; H01L 29/423; H01L 29/66

(52) U.S. Cl. CPC H01L 29/7869; H01L 29/42384; H01L 21/44; H01L 29/78606; H01L 29/66969; H01L 21/02565; H01L 29/45; H01L 21/0271
USPC 257/43; 438/104

(57) ABSTRACT

This semiconductor device (100A) includes: a gate electrode (3); a gate insulating layer (4); an oxide layer (50) which is formed over the gate insulating layer (4) and which includes a semiconductor region (51) and a first conductor region (55) that contacts with the semiconductor region (51) and where the semiconductor region (51) at least partially overlaps with the gate electrode (3) with the gate insulating layer (4) interposed between them; a protective layer (8b) covering the upper surface of the semiconductor region (51); source and drain electrodes (6s, 6d) electrically connected to the semiconductor region (51); and a transparent electrode (9) arranged so as to overlap at least partially with the first conductor region (55) with a dielectric layer interposed between them. The drain electrode (6d) contacts with the first conductor region (55). When viewed along a normal to the substrate, an end portion of the protective layer (8b) is substantially aligned with an end portion of the drain, source or gate electrode (6d, 6s, 3), and at least a portion of a boundary between the semiconductor region (51) and the first conductor region (55) is substantially aligned with the end portion of the protective layer (8b).

### TECHNICAL FIELD

The present invention relates to a semiconductor device which has been formed using an oxide semiconductor and a method for fabricating such a device, and more particularly relates to an active-matrix substrate for use in a liquid crystal display device or an organic EL display device and a method for fabricating such a substrate. In this description, the “semiconductor devices” include an active-matrix substrate and a display device which uses the active-matrix substrate.

### BACKGROUND ART

An active-matrix substrate for use in a liquid crystal display device and other devices includes switching elements such as thin-film transistors (which will be simply referred to herein as “TFTs”), each of which is provided for an associated one of pixels. An active-matrix substrate including TFTs as switching elements is called a “TFT substrate”.

As for TFTs, a TFT which uses an amorphous silicon film as its active layer (and will be referred to herein as an “amorphous silicon TFT”) and a TFT which uses a polysilicon film as its active layer (and will be referred to herein as a “polysilicon TFT”) have been used extensively.

Recently, people have proposed that an oxide semiconductor be used as a material for the active layer of a TFT instead of amorphous silicon or polysilicon. Such a TFT will be referred to herein as an “oxide semiconductor TFT”. Since an oxide semiconductor has higher mobility than amorphous silicon, the oxide semiconductor TFT can operate at higher speeds than an amorphous silicon TFT. Also, such an oxide semiconductor film can be formed by a simpler process than a polysilicon film.

Patent Document No. 1 discloses a method for fabricating a TFT substrate including oxide semiconductor TFTs. According to the method disclosed in Patent Document No. 1, a TFT substrate can be fabricated in a reduced number of manufacturing process steps by forming a pixel electrode with the resistance of the oxide semiconductor layer locally decreased.

Recently, as the definition of liquid crystal display devices and other devices has become higher and higher, a decrease in pixel aperture ratio has become an increasingly serious problem. In this description, the “pixel aperture ratio” refers herein to the ratio of the combined area of pixels (e.g., the combined area of regions which transmit light that contributes to a display operation in a transmissive liquid crystal display device) to the overall display area. In the following description, the “pixel aperture ratio” will be simply referred to herein as an “aperture ratio”.

Among other things, a medium to small sized transmissive liquid crystal display device to be used in a mobile electronic device has so small a display area that each of its pixels naturally has a very small area and the aperture ratio will decrease particularly significantly when the definition is increased. On top of that, if the aperture ratio of a liquid crystal display device to be used in a mobile electronic device decreases, the luminance of the backlight needs to be increased to achieve an intended brightness, thus causing an increase in power dissipation, too, which is also a problem.

To achieve a high aperture ratio, the combined area occupied by a TFT, a storage capacitor, and other elements of a non-transparent material in each pixel may be decreased. However, naturally, the TFT and the storage capacitor should have their minimum required size to perform their function. When oxide semiconductor TFTs are used as TFTs, the TFTs can have a smaller size than when amorphous silicon TFTs are used, which is advantageous. It should be noted that in order to maintain a voltage that has been applied to the liquid crystal layer of a pixel (which is called a “liquid crystal capacitor” electrically), the “storage capacitor” is provided electrically in parallel with the liquid crystal capacitor. In general, at least a portion of the storage capacitor is arranged so as to overlap with the pixel.

### CITATION LIST

### Patent Literature

Patent Document No. 1: Japanese Laid-Open Patent Publication No. 2011-91279

### SUMMARY OF INVENTION

### Technical Problem

However, demands for increased aperture ratios are too huge to satisfy just by using oxide semiconductor TFTs. Meanwhile, as the prices of display devices have become lower and lower year after year, development of a technology for manufacturing high-aperture-ratio display devices at a lower cost is awaited.

Also, the present inventors discovered and confirmed via experiments that when the method disclosed in Patent Document No. 1 was adopted, the reliability might decrease due to a low degree of contact between the oxide semiconductor film and the source line layer. This respect will be described in detail later.

Thus, a primary object of an embodiment of the present invention is to provide a semiconductor device which can be fabricated by a simpler process and which can contribute to realizing a display device with higher definition and a higher aperture ratio than conventional ones and with a good degree of reliability and also provide a method for fabricating such a semiconductor device.

### Solution to Problem

A semiconductor device according to an embodiment of the present invention includes: a substrate; a gate electrode formed on the substrate; a gate insulating layer formed over the gate electrode; an oxide layer which is formed on the gate insulating layer and which includes a semiconductor region and a first conductor region that contacts with the semiconductor region and where the semiconductor region at least partially overlaps with the gate electrode with the gate insulating layer interposed between them; a protective layer covering the upper surface of the semiconductor region; source and drain electrodes electrically connected to the semiconductor region; and a transparent electrode arranged so as to overlap at least partially with the first conductor region with a dielectric layer interposed between them. The drain electrode contacts with the first conductor region. When viewed along a normal to the substrate, an end portion of the protective layer is substantially aligned with an end portion of the drain electrode, an end portion of the source electrode or an end portion of the gate electrode, and at least a portion of a boundary between the semiconductor region and the first conductor region is substantially aligned with the end portion of the protective layer.

In one preferred embodiment, when viewed along a normal to the substrate, the semiconductor region is arranged inside of a profile of the gate electrode.

In one preferred embodiment, the oxide layer further includes a second conductor region located on the other side of the semiconductor region opposite from the first conductor region. The drain electrode contacts with an upper surface of the first conductor region of the oxide layer and the source electrode contacts with an upper surface of the second conductor region of the oxide layer. The transparent electrode is an upper transparent electrode arranged over the oxide layer with the dielectric layer interposed between them. When viewed along a normal to the substrate, the end portion of the protective layer is substantially aligned with the end portion of the gate electrode, and at least a portion of boundaries between the semiconductor region and the first and second conductor regions is substantially aligned with the end portion of the protective layer.

In one preferred embodiment, when viewed along a normal to the substrate, the semiconductor region is arranged inside of a profile of a region which overlaps with at least one of the gate, source and drain electrodes.

In one preferred embodiment, the source and drain electrodes are formed between the gate insulating layer and the oxide layer. The semiconductor region of the oxide layer contacts with respective upper surfaces of the source and drain electrodes. When viewed along a normal to the substrate, at least a portion of the boundary between the semiconductor region and the first conductor region is substantially aligned with the end portion of the drain electrode.

In one preferred embodiment, the transparent electrode is an upper transparent electrode arranged over the oxide layer with the dielectric layer interposed between them.

In one preferred embodiment, the transparent electrode is a lower transparent electrode arranged between the oxide layer and the substrate and the dielectric layer includes at least a portion of the gate insulating layer.

In one preferred embodiment, the semiconductor device further includes a source-drain connecting portion, the source-drain connecting portion includes: a gate connecting layer formed out of the same conductive film as the gate electrode; a source connecting layer formed out of the same conductive film as the source electrode; and a transparent connecting layer formed out of the same transparent conductive film as the upper transparent electrode. The source connecting layer and the gate connecting layer are electrically connected together via the transparent connecting layer.

In one preferred embodiment, the semiconductor device further includes a source-drain connecting portion, the source-drain connecting portion includes: a gate connecting layer formed out of the same conductive film as the gate electrode; and a source connecting layer formed out of the same conductive film as the source electrode. The source connecting layer contacts with the gate connecting layer inside a hole formed in the gate insulating layer.

In one preferred embodiment, the oxide layer includes In, Ga and Zn.

A method for fabricating a semiconductor device according to an embodiment of the present invention includes the steps of: (A) providing a substrate having a gate electrode and a gate insulating layer formed thereon; (B) forming an oxide semiconductor layer over the gate insulating layer; (C) forming a resistance-lowering-processing mask on the oxide semiconductor layer so as to cover a portion of the oxide semiconductor layer, the portion being located over the gate electrode, the step (C) including the steps of: (C1) forming a resist film on the oxide semiconductor layer, and (C2) exposing the resist film to radiation from an opposite side of the surface of the substrate using the gate electrode as a mask, thereby forming a resist layer; and (D) lowering the resistance of a portion of the oxide semiconductor layer which is not covered with the resistance-lowering-processing mask to define a first conductor region, and turning the rest of the oxide semiconductor layer which has not had its resistance lowered into a semiconductor region, thereby forming an oxide layer including the semiconductor region and the first conductor region.

In one preferred embodiment, the method further includes the steps of: (E) forming source and drain electrodes so that the source and drain electrodes contact with an upper surface of the oxide layer; and (F) forming a dielectric layer over the oxide layer and then forming an upper transparent electrode so that the upper transparent electrode overlaps with at least a portion of the first conductor region with the dielectric layer interposed between them.

In one preferred embodiment, the step (C) includes the step of forming a protective film on the oxide semiconductor layer before the step (C1). The step (C2) includes forming the resist layer on the protective film. And the step (C) further includes the step of patterning the protective film using the resist layer as a mask, thereby forming a protective layer as the resistance-lowering-processing mask, after the step (C2).

A method for fabricating a semiconductor device according to another embodiment of the present invention includes the steps of: (a) providing a substrate having a gate electrode and a gate insulating layer formed thereon; (b) forming source and drain electrodes on the gate insulating layer; (c) forming an oxide semiconductor layer covering the source and drain electrodes; (d) forming a resistance-lowering-processing mask on the oxide semiconductor layer so as to cover at least a portion of the oxide semiconductor layer, the portion being located over the gate electrode, the step (d) including the steps of: (d1) forming a resist film on the oxide semiconductor layer, and (d2) exposing the resist film to radiation from an opposite side of the surface of the substrate using the gate electrode as a mask, thereby forming a resist layer; and (e) lowering the resistance of a portion of the oxide semiconductor layer which is not covered with the resistance-lowering-processing mask to define a first conductor region, and turning the rest of the oxide semiconductor layer which has not had its resistance lowered into a semiconductor region, thereby forming an oxide layer including the semiconductor region and the first conductor region.

In one preferred embodiment, the method further includes the step (f) of forming a dielectric layer so that the dielectric layer contacts with an upper surface of the oxide layer and then forming an upper transparent electrode so that the upper transparent electrode overlaps with at least a portion of the first conductor region with the dielectric layer interposed between them.

In one preferred embodiment, the method further includes the step of forming a lower transparent electrode on the substrate before the step (b). In the step (e), the first conductor region is arranged so as to overlap with the lower transparent electrode with at least a portion of the gate insulating layer interposed between them.

In one preferred embodiment, the step (d) includes forming a protective film on the oxide semiconductor layer before the step (d1). The step (d2) includes forming the resist layer on the protective film. And the method further includes the step of patterning the protective film using the resist layer as a mask to form a protective layer as the resistance-lowering-processing mask after the step (d2).

In one preferred embodiment, the oxide semiconductor layer includes In, Ga and Zn.

### Advantageous Effects of Invention

An embodiment of the present invention provides a TFT substrate which can be fabricated by a simpler process and which can contribute to realizing a display device with higher definition and a higher aperture ratio than conventional ones and also provides a method for fabricating such a TFT substrate.

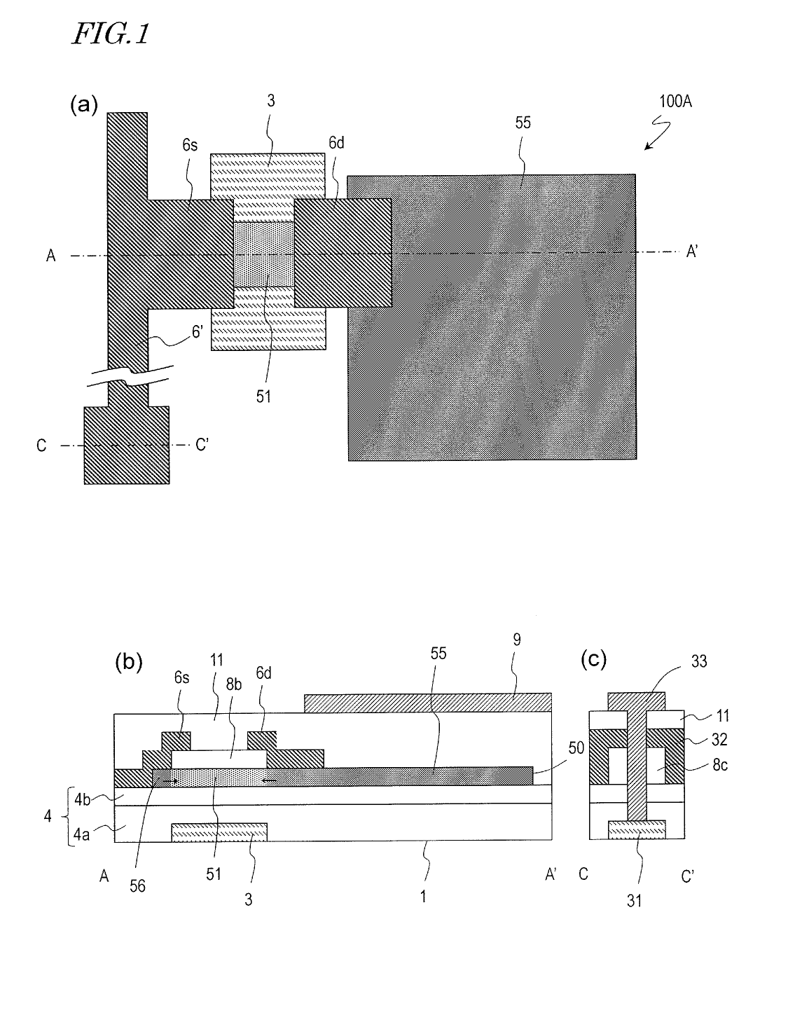

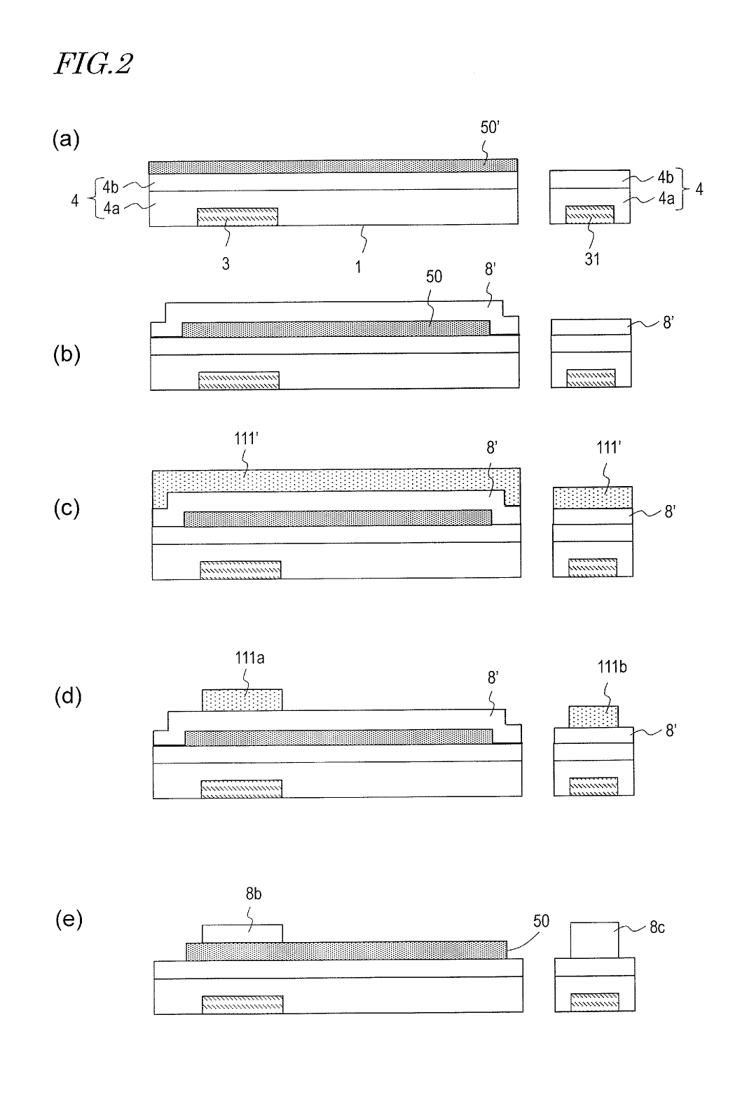

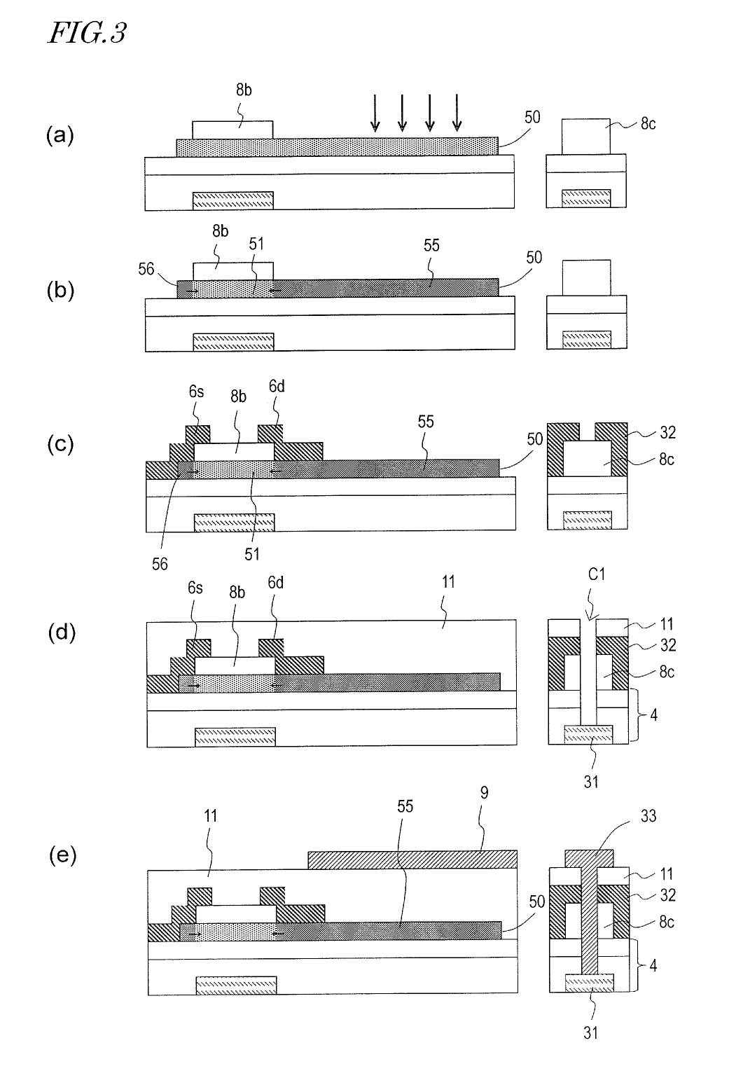

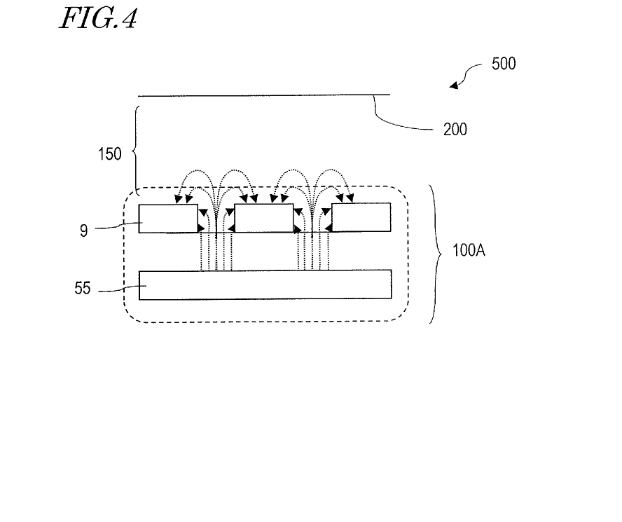

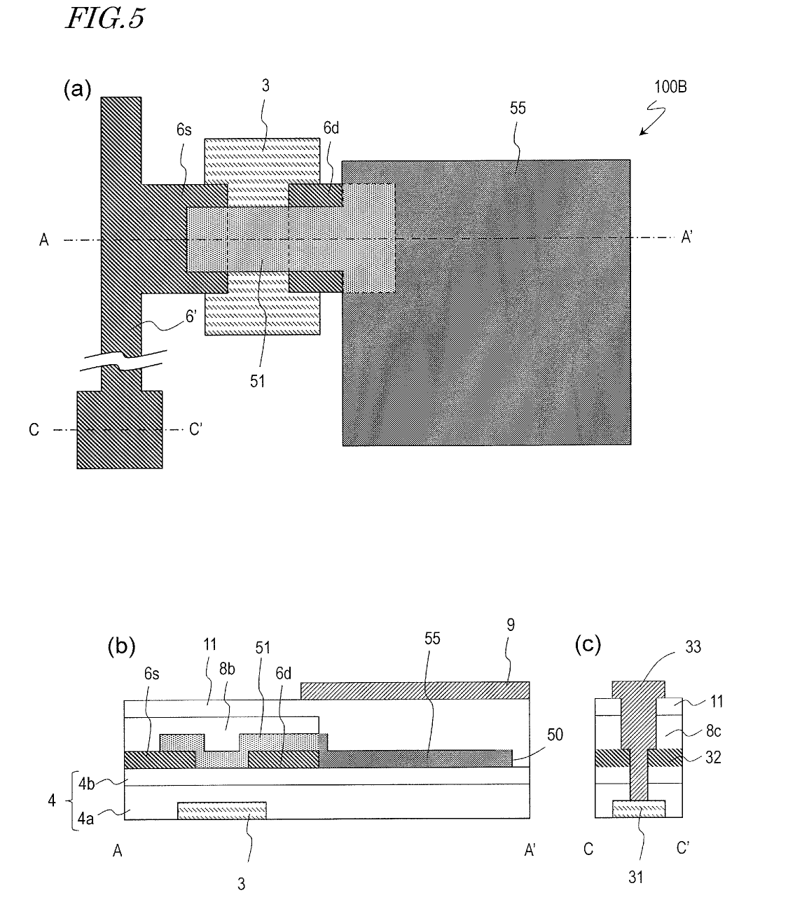

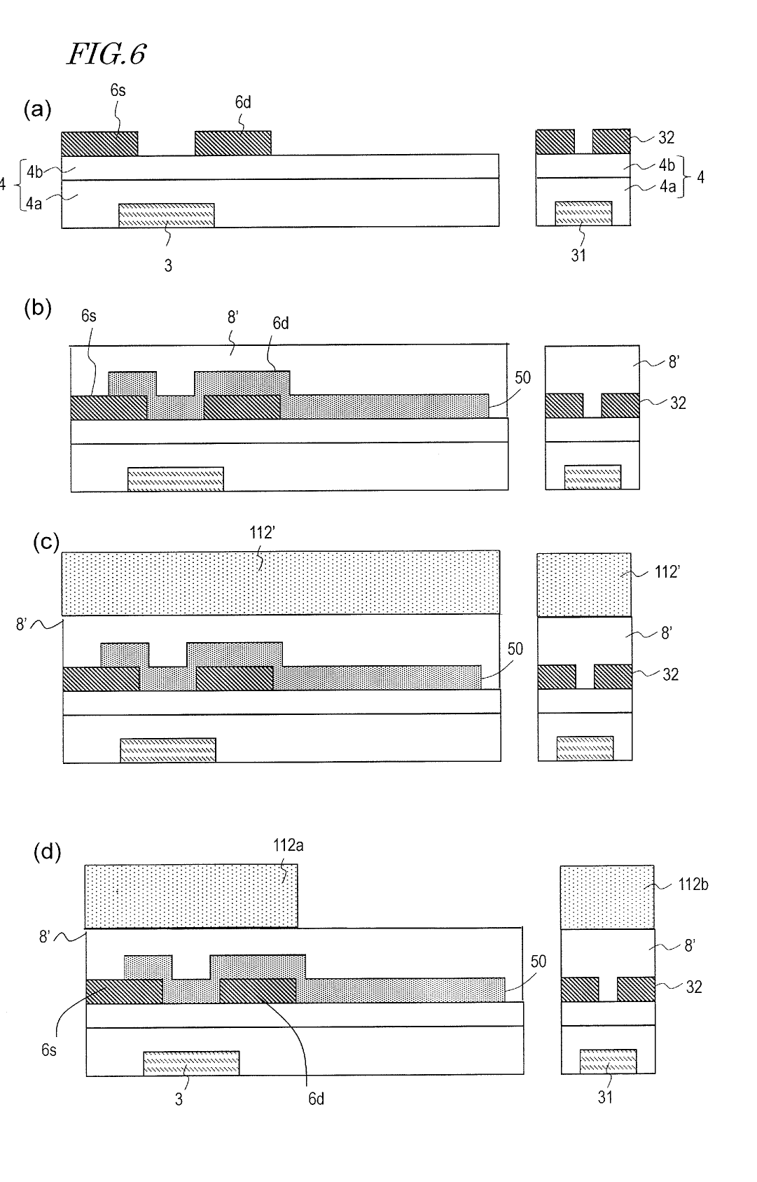

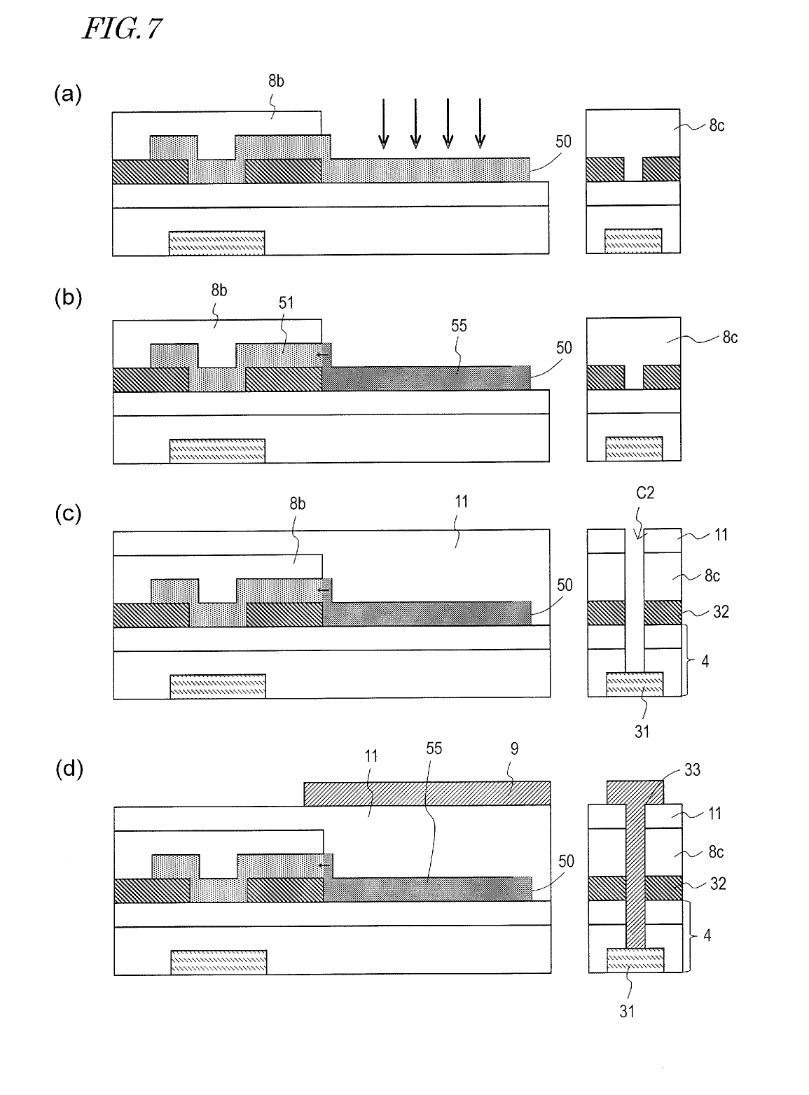

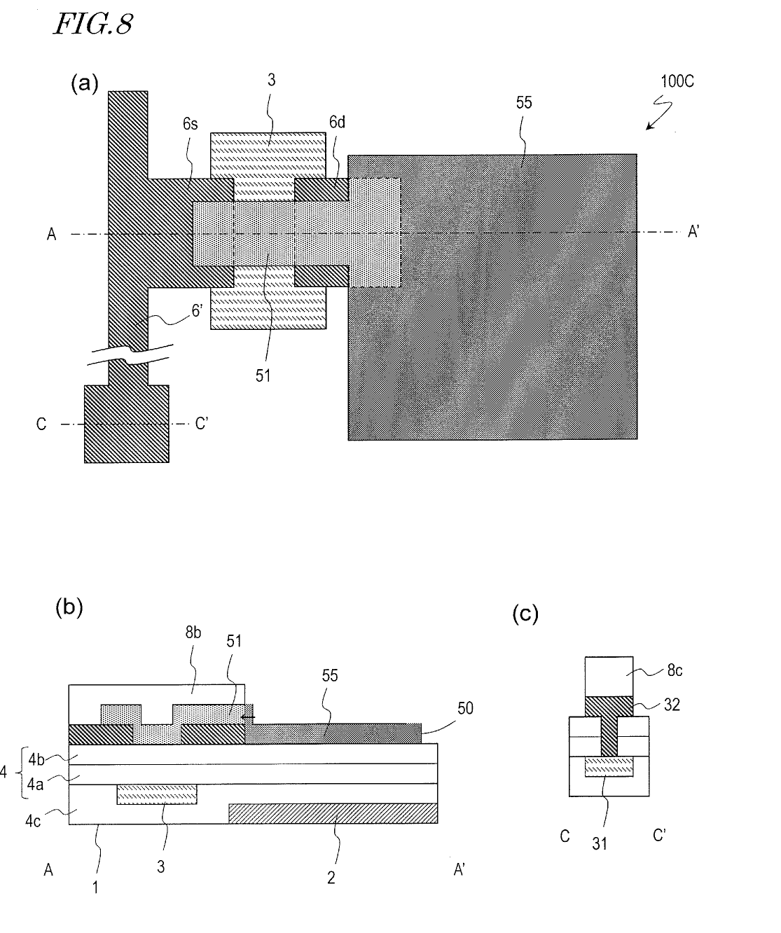

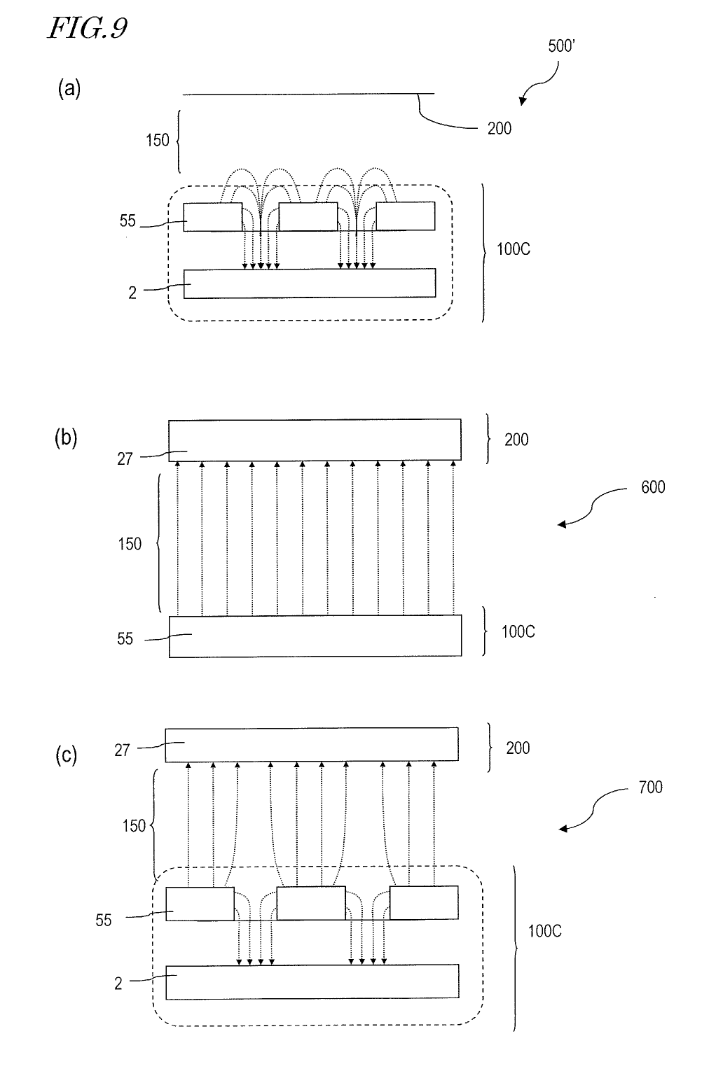

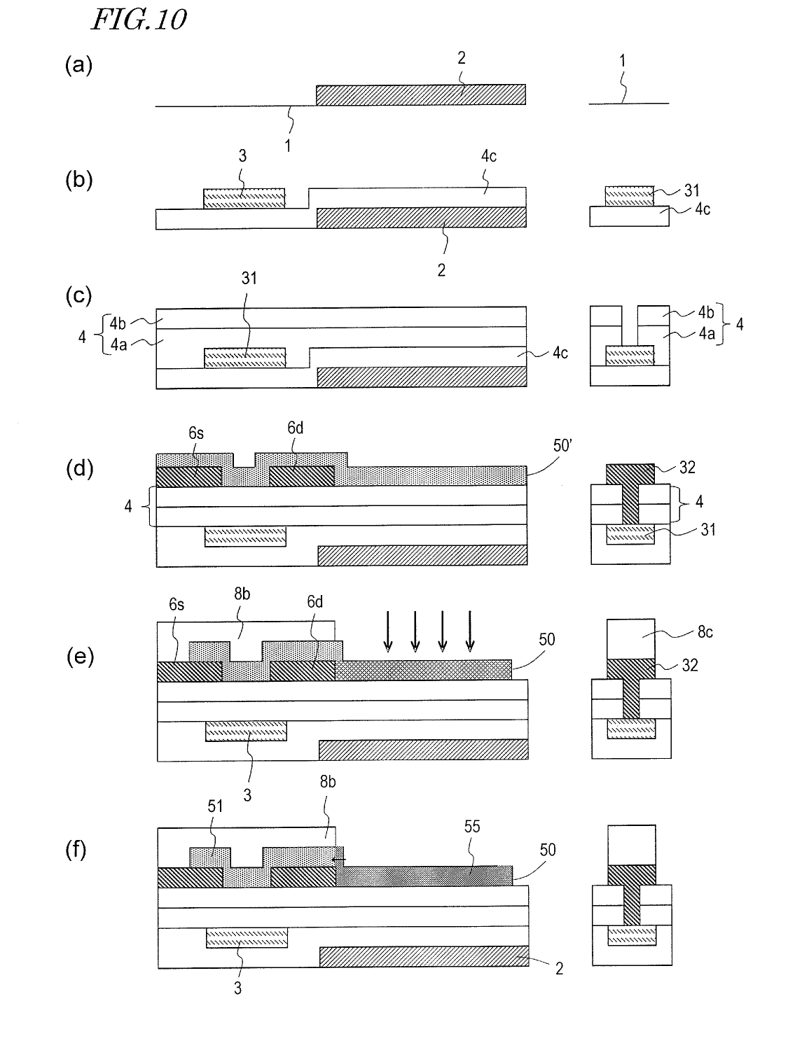

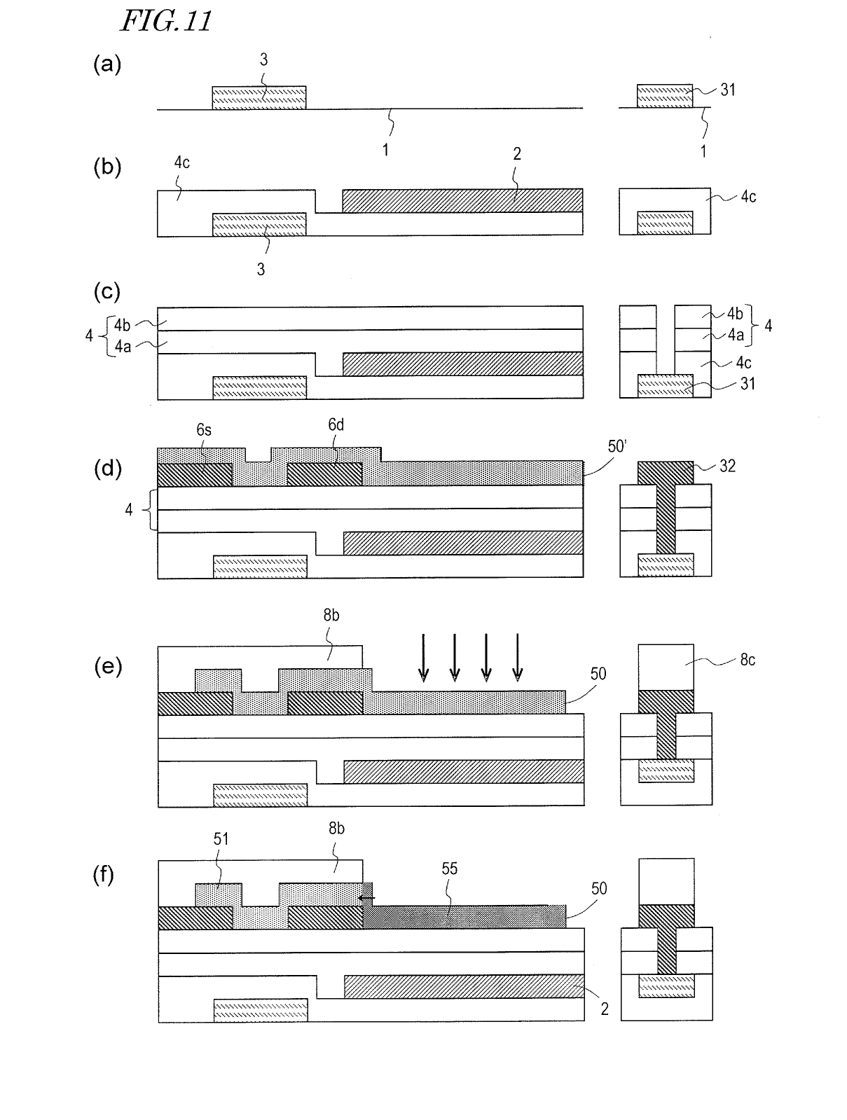

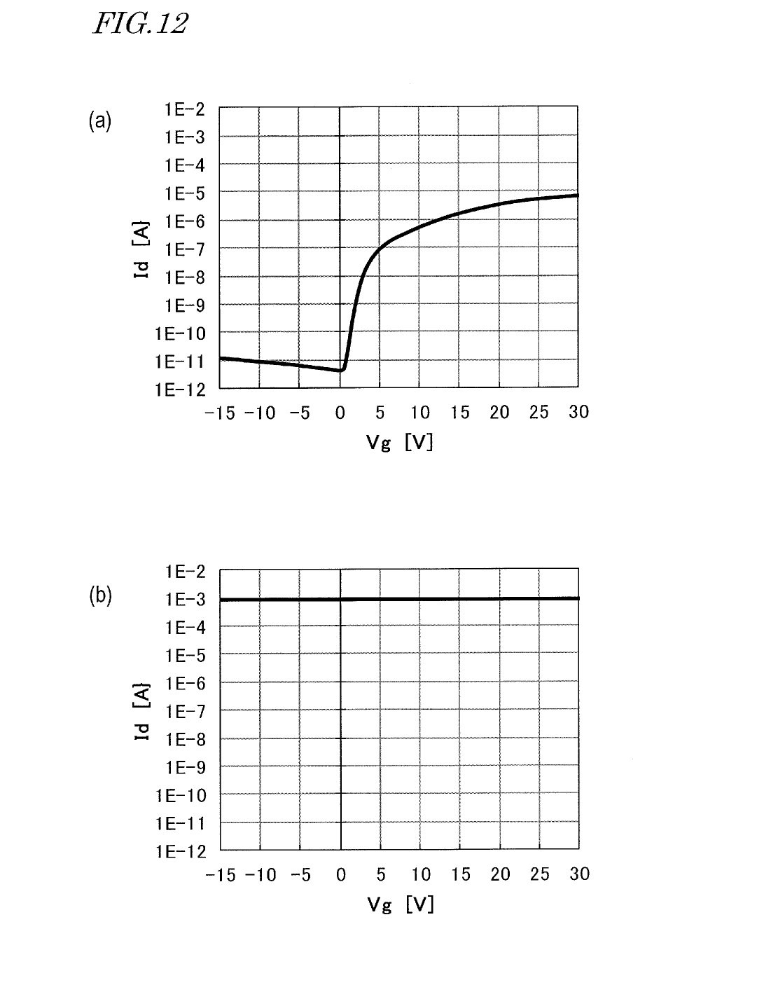

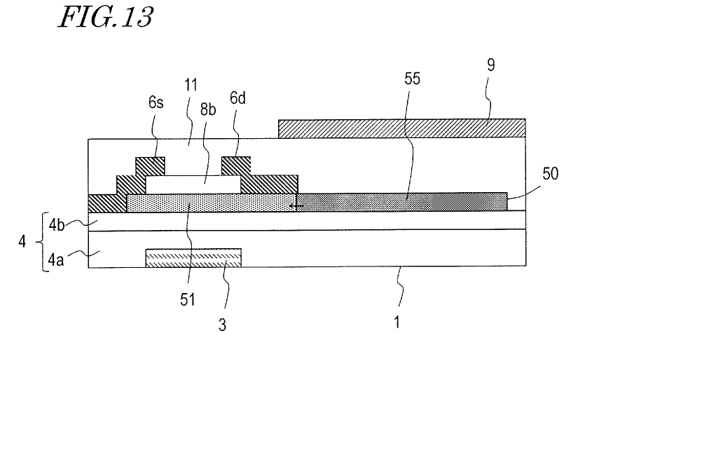

### BRIEF DESCRIPTION OF DRAWINGS

[FIG. 1] (a) is a schematic plan view illustrating a TFT substrate 100A according to a first embodiment of the present invention, and (b) and (c) are schematic cross-sectional views of the TFT substrate 100A as respectively viewed on the planes A-A′ and C-C′ shown in (a).

[FIG. 2] (a) through (e) are schematic cross-sectional views illustrating respective manufacturing process steps to fabricate the TFT substrate 100A as viewed on the planes A-A′ and C-C′ shown in FIG. 1(a).

[FIG. 3] (a) through (e) are schematic cross-sectional views illustrating respective manufacturing process steps to fabricate the TFT substrate 100A as viewed on the planes A-A′ and C-C′ shown in FIG. 1(a).

[FIG. 4] A schematic cross-sectional view illustrating a liquid crystal display device 500 including the TFT substrate 100A.

[FIG. 5] (a) is a schematic plan view illustrating a TFT substrate 100B according to a second embodiment of the present invention, and (b) and (c) are schematic cross-sectional views of the TFT substrate 100B as respectively viewed on the planes A-A′ and C-C′ shown in (a).

[FIG. 6] (a) through (d) are schematic cross-sectional views illustrating respective manufacturing process steps to fabricate the TFT substrate 100B as viewed on the planes A-A′ and C-C′ shown in FIG. 5(a).

[FIG. 7] (a) through (d) are schematic cross-sectional views illustrating respective manufacturing process steps to fabricate the TFT substrate 100B as viewed on the planes and C-C′ shown in FIG. 5(a).

[FIG. 8] (a) is a schematic plan view illustrating a TFT substrate 100C according to a third embodiment of the present invention, and (b) and (c) are schematic cross-sectional views of the TFT substrate 100C as respectively viewed on the planes A-A′ and C-C′ shown in (a).

[FIG. 9] (a) to (c) are schematic cross-sectional views of a display device including the TFT substrate 100C.

[FIG. 10] (a) through (f) are schematic cross-sectional views illustrating respective manufacturing process steps to fabricate the TFT substrate 100C as viewed on the planes A-A′ and C-C′ shown in FIG. 8(a).

[FIG. 11] (a) through (f) are schematic cross-sectional views illustrating respective manufacturing process steps to fabricate another TFT substrate according to the third embodiment as viewed on the planes A-A′ and C-C′ shown in FIG. 8(a).

[FIG. 12] (a) is a graph showing a gate voltage-drain current curve of an oxide semiconductor TFT having a configuration in which an oxide insulating layer has been formed so as to contact with an oxide semiconductor layer. (b) is a graph showing a gate voltage-drain current curve of an oxide semiconductor TFT having a configuration in which a reducing insulating layer has been formed so as to contact with an oxide semiconductor layer.

[FIG. 13] A cross-sectional view illustrating another TFT substrate according to the first embodiment.

### DESCRIPTION OF EMBODIMENTS

### Embodiment 1

Hereinafter, a semiconductor device as a first embodiment of the present invention will be described with reference to the accompanying drawings. The semiconductor device of this embodiment includes a thin-film transistor with an active layer made of an oxide semiconductor (which will be referred to herein as an “oxide semiconductor TFT”). It should be noted that the semiconductor device of this embodiment just needs to include an oxide semiconductor TFT and is broadly applicable to an active-matrix substrate and various kinds of display devices and electronic devices.

In the following description, a semiconductor device as an embodiment of the present invention will be described as being applied to an oxide semiconductor TFT for use in a liquid crystal display device.

FIG. 1(a) is a schematic plan view illustrating a TFT substrate 100A according to this embodiment. FIG. 1(b) is a cross-sectional view of the TFT substrate 100A as viewed on the plane A-A′ shown in FIG. 1(a). And FIG. 1(c) is a cross-sectional view illustrating the source-gate connecting portion of the TFT substrate 100A.

This TFT substrate 100A includes a substrate 1, a gate electrode 3 which has been formed on the substrate 1, a gate insulating layer 4 which has been formed over the gate electrode 3, and an oxide layer 50 which has been formed on the gate insulating layer 4. In this embodiment, the gate insulating layer 4 has a multilayer structure including a lower insulating layer 4a and an upper insulating layer 4b. The oxide layer 50 includes a semiconductor region 51 and conductor regions 55 and 56. The semiconductor region 51 is arranged so as to overlap at least partially with the gate electrode 3 with the gate insulating layer 4 interposed between them and functions as an active layer for the TFT. Also, the conductor regions 55 and 56 are in contact with the semiconductor region 51. The conductor region 55 is located on the drain side of the semiconductor region 51, while the conductor region 56 is located on the source side of the semiconductor region 51.

A protective layer 8b is arranged on the oxide layer 50 so as to contact with the upper surface of the semiconductor region 51. Source and drain electrodes 6s and 6d have been formed on the oxide layer 50 and the protective layer 8b. The source electrode 6s contacts with at least a part of the upper surface of the conductor region 56. The drain electrode 6d contacts with at least a part of the upper surface of the conductor region 55. Thus, the source and drain electrodes 6s and 6d are electrically connected to the semiconductor region 51 via the conductor regions 55 and 56. In this manner, according to this embodiment, the conductor regions 55 and 56 function as a drain (contact) region and a source (contact) region, respectively. Also, in the example illustrated in FIG. 1, the conductor region 55 can function as not only a drain region but also a transparent electrode (such as a pixel electrode) as well.

An upper insulating layer (passivation film) 11 has been formed over the source and drain electrodes 6s and 6d. An upper transparent electrode 9 has been formed on the upper insulating layer 11. At least part of the upper transparent electrode 9 overlaps with the conductor region 55 with the upper insulating layer 11 interposed between them to form a storage capacitor.

The conductor region 55 of the oxide layer 50 has a lower electrical resistance than the semiconductor region 51. The electrical resistance of the conductor region 55 may be 100 kΩ/□ or less, for example, and is suitably 10 kΩ/□ or less. The conductor region 55 may be formed by locally lowering the resistance of an oxide semiconductor film, for example. Although it depends on what processing method is taken to lower the resistance, the conductor region 55, for example, may be doped more heavily with a dopant (such as boron) than the semiconductor region 51 is.

Optionally, the TFT substrate 100A may further include a source-gate connecting portion to connect respective portions of a source line layer and a gate line layer together.

As shown in FIG. 1(c), the source-gate connecting portion includes a gate connecting layer 31 which has been formed out of the same conductive layer as the gate electrode 3 (which will be referred to herein as a “gate line layer”), a source connecting layer 32 which has been formed out of the same conductive layer as the source electrode 6s (which will be referred to herein as a “source line layer”), and a transparent connecting layer 33 which has been formed out of the same transparent conductive film as the upper transparent electrode 9. The source connecting layer 32 and the gate connecting layer 31 are electrically connected together via the transparent connecting layer 33.

In the example illustrated in FIG. 1, the gate insulating layer 4 has been extended onto the gate connecting layer 31. A protective layer 8c is arranged on the gate insulating layer 4. The protective layer 8c has been formed out of the same protective film as the protective layer 8b. The protective layer 8c is covered with the source connecting layer 32 and the upper insulating layer 11. The transparent connecting layer 33 is arranged so as to contact with the gate connecting layer 31 inside a hole formed in the upper insulating layer 11, the source connecting layer 32, the protective layer 8b and the gate insulating layer 4.

The TFT substrate 100A of this embodiment has such a configuration, and therefore, can achieve the following effects.

In this TFT substrate 100A, by locally lowering the resistance of the oxide layer 50, a conductor region 55 to be a pixel electrode may be defined and the rest of the oxide layer 50 which remains the same semiconductor can turn into a semiconductor region 51 to be the active layer of a TFT. Thus, the manufacturing process can be simplified.

In addition, according to this embodiment, at least a part of the upper transparent electrode 9 overlaps with the conductor region (lower transparent electrode) 55 with the upper insulating layer 11 interposed between them. As a result, a storage capacitor is formed in the region where these two transparent electrodes overlap with each other. However, this storage capacitor is transparent (i.e., can transmit visible light), and does not decrease the aperture ratio. Consequently, this TFT substrate 100A can have a higher aperture ratio than a conventional TFT substrate with a storage capacitor including a non-transparent electrode which has been formed out of a metal film (such as a gate metal layer or a source metal layer). On top of that, since the aperture ratio is not decreased by the storage capacitor, the capacitance value of the storage capacitor (i.e., the area of the storage capacitor) can be increased as needed, which is also advantageous. Optionally, the upper transparent electrode 9 may be formed so as to cover almost the entire pixel (but the area where the TFT is present).

According to this embodiment, a mask for use to perform a resistance lowering process on the oxide layer 50 (which will be sometimes referred to herein as a “resistance lowering processing mask”) is formed by a self-alignment process. Specifically, a resist film which has been formed on the oxide layer 50 is exposed to radiation coming from the back surface of the substrate 1 (which will be referred to herein as a “back surface exposure process”). Since the gate electrode 3 serves as a mask in this process step, a predetermined region of the resist film is not exposed. As a result, a resist layer is formed so as to partially cover the oxide layer 50. This resist layer may be used as a resistance lowering processing mask. Alternatively, as the resistance lowering processing mask, an insulating layer which has been patterned using the resist layer as an etching mask (such as the protective layer 8b) may also be used. In the example illustrated in FIG. 1, the protective layer 8b that covers the channel portion of the oxide layer 50 is formed by using the back surface exposure process. And by performing a resistance lowering process on the oxide layer 50 using the protective layer 8b as a mask, conductor regions 55 and 56 are defined as portions of the oxide layer 50. As a result, when viewed along a normal to the substrate 1, a portion of the oxide layer 50 which does not overlap with the gate electrode 3 has its resistance lowered to turn into a conductor region 55, while the other portion that does overlap with the gate electrode 3 is left as a semiconductor region 51. Consequently, the number of manufacturing process steps and the manufacturing cost can be cut down, and the yield can be increased.

If the TFT substrate 100A is fabricated by adopting such a self-alignment process, the end portion of the protective layer 8b will be substantially aligned with that of the gate electrode 3 when viewed along a normal to the substrate 1. In addition, at least a portion of the boundary between the semiconductor region 51 and the conductor regions and 56 will also be substantially aligned with the end portion of the protective layer 8b. In this description, those end portions are also regarded as being “substantially aligned with” each other even if that end portion of the protective layer 8b is located outside or inside of that of the gate electrode 3 that has been used as an etching mask (due to over-etching, for example) depending on the etching process condition. Those end portions can also be said to be substantially aligned with each other even if the boundary between the semiconductor region 51 and the conductor regions 55 and 56 is located inside of the end portion of the protective layer 8b or the gate electrode 3 due to diffusion of dopants included in the conductor region 55, for example. In that case, when viewed along a normal to the substrate 1, the profile of the semiconductor region 51 will be inside that of the gate electrode 3.

In this manner, according to this embodiment, the semiconductor region 51 is arranged inside of the profile of the gate electrode 3. It should be noted that if the semiconductor region 51 is “arranged inside of” the profile of the gate electrode 3, the end portion of the semiconductor region 51 may not only be located inside of, but also be aligned with, that of the gate electrode 3.

As mentioned above, Patent Document No. 1 teaches forming a pixel electrode by lowering the resistance of an oxide semiconductor film locally. However, the present inventors discovered and confirmed via experiments that the method of Patent Document No. 1 had the following problem.

Specifically, according to the method proposed in Patent Document No. 1, when viewed along a normal to the TFT substrate, there is a gap between the pixel electrode and drain electrode, and the pixel electrode cannot be formed to reach the end portion of the drain electrode, which is a problem. In contrast, according to this embodiment, when viewed along a normal to the substrate 1, the conductor region 55 is arranged so that its end portion on the channel side overlaps with the drain electrode. Consequently, there is no gap between a portion of the conductor region 55 functioning as a pixel electrode and the drain electrode, and the aperture ratio can be further increased.

Also, according to Patent Document No. 1, an oxide layer and a source line layer are patterned by the half-tone exposure technique in order to reduce the number of masks to use in the manufacturing process. If this technique is adopted, however, the source line layer and the oxide layer cannot be patterned independently of each other. That is why a data signal line (i.e., source line) to be formed in the display area of a display device, an extended line around the display area, a terminal connecting portion and other members will have a multilayer structure consisting of an oxide layer and source line layer. In that case, although it depends on the material of the source electrode, due to the heat applied during the manufacturing process (i.e., the heat that is intentionally applied to the substrate to perform an annealing process or a film deposition process), the degree of close contact with the oxide layer and the source line layer will decrease so much as to cause peeling easily at their interface. For that reason, it is sometimes difficult to apply such a technique to an array substrate on which not only pixel transistors but also a peripheral circuit are integrated together. To avoid such a problem, the process temperature could be lowered. In that case, however, it would be difficult to achieve the intended TFT characteristic with certainty and the reliability could decrease.

On the other hand, since a self-alignment process using exposing radiation coming from the back surface of the substrate 1 is adopted according to this embodiment, the source line layer and the oxide layer can be patterned independently of each other using separate masks without increasing the number of masks to use in the manufacturing process. As a result, extended lines, terminal connecting portions and other members can be formed out of only the source line layer, not as a multilayer structure consisting of the source line layer and the oxide layer, and peeling mentioned above can be avoided. In addition, not only pixel TFTs but also a peripheral circuit can be integrated together on the substrate. Furthermore, according to this embodiment, a storage capacitor that contributes to using incoming light even more efficiently without sacrificing the aperture area of a pixel can be formed. Consequently, this embodiment can be used even more effectively in medium to small sized displays such as smart phones and tablets which have become increasingly popular lately.

Hereinafter, the respective components of this TFT substrate 100A will be described in detail one by one.

The substrate 1 is typically a transparent substrate and may be a glass substrate, for example, but may also be a plastic substrate. Examples of the plastic substrates include a substrate made of either a thermosetting resin or a thermoplastic resin and a composite substrate made of these resins and an inorganic fiber (such as glass fiber or a non-woven fabric of glass fiber). A resin material with thermal resistance may be polyethylene terephthalate (PET), polyethylene naphthalate (PEN), polyether sulfone (PES), an acrylic resin, or a polyimide resin, for example. Also, when used in a reflective liquid crystal display device, the substrate 1 may also be a silicon substrate.

The gate electrode 3 is electrically connected to a gate line 3′. The gate electrode 3 and the gate line 3′ may have a multilayer structure, of which the upper layer is a W (tungsten) layer and the lower layer is a TaN (tantalum nitride) layer, for example. Alternatively, the gate electrode 3 and the gate line 3′ may also have a multilayer structure consisting of Mo (molybdenum), Al (aluminum) and Mo layers or may even have a single-layer structure, a double layer structure, or a multilayer structure consisting of four or more layers. Still alternatively, the gate electrode 3a may be made of an element selected from the group consisting of Cu (copper), Al, Cr (chromium), Ta (tantalum), Ti (titanium), Mo and w or an alloy or metal nitride which is comprised mostly of any of these elements. The thickness of the gate electrode 3 may fall within the range of about 50 nm to about 600 nm, for example. In this embodiment, the gate electrode 3 has a thickness of approximately 420 nm.

The gate insulating layer 4 may also be a single layer or a multilayer structure of SiO₂ (silicon dioxide), SiNₓ (silicon nitride), SiOₓN_{y} (silicon oxynitride, where x>y), SiNₓO_{y} (silicon nitride oxide, where x>y), Al₂O₃ (aluminum oxide), or tantalum oxide (Ta₂O₅). The thickness of the gate insulating layer 4 suitably falls within the range of about 50 nm to about 600 nm. To prevent dopants from diffusing from the substrate 1, the insulating layer 4a is suitably made of SiNₓ or SiNₓO_{y} (silicon oxynitride, where x>y). Moreover, to prevent the semiconductor properties of the oxide semiconductor region 51 from deteriorating, the insulating layer 4b is suitably made of either SiO₂ or SiOₓN_{y} (silicon nitride oxide, where x>y). Furthermore, to form a dense gate insulating layer 4 which causes little gate leakage current at low temperatures, the gate insulating layer 4 is suitably formed using a rare gas of Ar (argon), for example.

The gate insulating layer 4 of this embodiment includes two insulating layers 4a and 4b, of which the one contacting directly with the semiconductor region 51 of the oxide layer 50 (e.g., the insulating layer 4b in this embodiment) suitably includes an oxide insulating layer. If the oxide insulating layer directly contacts with the semiconductor region 51, oxygen included in the oxide insulating layer will be supplied to the semiconductor region 51, thus preventing oxygen deficiencies in the semiconductor region 51 from deteriorating the properties of the semiconductor. The insulating layer 4b may be an SiO₂ (silicon dioxide) layer, for example. The insulating layer 4a may be an SiNₓ (silicon nitride) layer, for example. In this embodiment, the insulating layer 4a may have a thickness of approximately 325 nm, the insulating layer 4b may have a thickness of approximately 50 nm, and the gate insulating layer 4 may have an overall thickness of approximately 375 nm, for example.

The oxide layer 50 may include In, Ga and Zn. For example, the oxide layer 50 may include an In—Ga—Zn—O based oxide. In this case, the In—Ga—Zn—O based oxide is a ternary oxide of In (indium), Ga (gallium) and Zn (zinc). The ratios (i.e., mole fractions) of In, Ga and Zn are not particularly limited. For example, In:Ga:Zn=2:2:1, In:Ga:Zn=1:1:1 or In:Ga:Zn=1:1:2 may be satisfied. In this embodiment, an In—Ga—Zn—O based oxide film including In, Ga and Zn at the ratio of 1:1:1 is used. If such an In—Ga—Zn—O based oxide film is used as the oxide layer 50, the semiconductor region 51 to be a channel region for a TFT becomes an In—Ga—Zn—O based semiconductor region. In this description, an In—Ga—Zn—O based oxide which exhibits a semiconductor property will be referred to herein as an “In—Ga—Zn—O based semiconductor”. A TFT, of which the active layer is an In—Ga—Zn—O based semiconductor region, has high mobility (which is more than 20 times as high as that of an a-Si TFT) and low leakage current (which is less than one hundredth of that of an a-Si TFT), and therefore, can be used effectively as a driver TFT and a pixel TFT.

The oxide layer 50 does not have to be formed out of an In—Ga—Zn—O based oxide film, but may also be formed out of a Zn—O based (ZnO) film, an In—Zn—O based (IZO™) film, a Zn—Ti—O based (ZTO) film, a Cd—Ge—O based film, a Cd—Pb—O based film, a CdO (cadmium oxide) film, an Mg—Zn—O based film, an In—Sn—Zn—O based oxide (such as In₂O₃—SnO₂—ZnO) or an In—Ga—Sn—O based oxide, for example. Furthermore, the oxide layer 50 may also be ZnO in an amorphous state, a polycrystalline state, or a microcrystalline state (which is a mixture of amorphous and polycrystalline states) to which one or multiple dopant elements selected from the group consisting of Group I, Group XIII, Group XIV, Group XV and Group XVII elements have been added, or may even be ZnO to which no dopant elements have been added at all. An amorphous oxide film is suitably used as the oxide layer 50, because the semiconductor device can be fabricated at a low temperature and can achieve high mobility in that case. The thickness of the oxide layer 50 may fall within the range of about 30 nm to about 100 nm, for example (e.g., approximately 50 nm).

The oxide layer 50 of this embodiment includes a high-resistance portion which functions as a semiconductor and a low-resistance portion which has a lower electrical resistance than the high-resistance portion does. In the example illustrated in FIG. 1, the high-resistance portion includes the semiconductor region 51, while the low-resistance portion includes the conductor regions 55 and 56. Such an oxide layer 50 may be formed by lowering the resistance of a portion of the oxide semiconductor film. Although it depends on what method is used to lower the resistance, the low-resistance portion may be doped more heavily with a p-type dopant (such as B (boron)) or an n-type dopant (such as P (phosphorus)) than the high-resistance portion is. The low-resistance portion may have an electrical resistance of 100 kΩ/□ or less, and suitably has an electrical resistance of 10 kΩ/□ or less.

The source line layer (including the source and drain electrodes 6s and 6d in this case) may have a multilayer structure comprised of Ti, Al and Ti layers, for example. Alternatively, the source line layer may also have a multilayer structure comprised of Mo, Al and Mo layers or may even have a single-layer structure, a double layer structure or a multilayer structure consisting of four or more layers. Furthermore, the source line layer may also be made of an element selected from the group consisting of Al, Cr, Ta, Ti Mo and W, or an alloy or metal nitride comprised mostly of any of these elements. The thickness of the source line layer may fall within the range of about 50 nm to about 600 nm (e.g., approximately 350 nm), for example.

The protective layer 8b is suitably made of an insulating oxide (such as SiO₂). If the protective layer 8b is made of an insulating oxide, it is possible to prevent the oxygen deficiencies in the semiconductor region 51 of the oxide layer from deteriorating the semiconductor properties. Alternatively, the protective layer 8b may also be made of SiON (which may be either silicon oxynitride or silicon nitride oxide), Al₂O₃ or Ta₂O₅, for example. The thickness of the protective layer 8b may fall within the range of about 50 nm to about 300 nm, for example. In this embodiment, the protective layer 8b has a thickness of about 150 nm, for example.

In this description, an insulating layer which is formed between the lower transparent electrode (conductor region) 55 and the upper transparent electrode 9 to produce storage capacitance there will be sometimes referred to herein as a “dielectric layer”. In this example, the upper insulating layer 11 becomes a dielectric layer. The dielectric layer may include SiNₓ, for example. Alternatively, the dielectric layer may also be made of SiOₓN_{y} (silicon oxynitride, where x>y), SiNₓO_{y} (silicon nitride oxide, where x>y), Al₂O₃ (aluminum oxide), or tantalum oxide (Ta₂O₅). The thickness of the dielectric layer may fall within the range of about 100 nm to about 500 nm (e.g., approximately 200 nm). Optionally, the upper insulating layer 11 may have a multilayer structure.

The upper transparent electrode 9 has been formed out of a transparent conductive film such as an ITO film or an IZO film. The thickness of the upper transparent electrode 9 may fall within the range of 20 nm to 200 nm. In this embodiment, the upper transparent electrode 9 has a thickness of about 100 nm.

(Method for Fabricating TFT Substrate 100A)

Hereinafter, an exemplary method for fabricating the TFT substrate 100A will be described.

FIGS. 2(a) through 2(f) and FIGS. 3(a) to 3(c) are schematic cross-sectional views illustrating an exemplary series of manufacturing process steps to fabricate the TFT substrate 100A. On these drawings, illustrated are cross-sectional structures of a portion of a display area including a TFT and a source-gate connecting portion.

First of all, as shown in FIG. 2(a), a gate electrode 3 and a gate connecting layer 31 are formed on a substrate 1. Next, a gate insulating layer 4 is deposited over the gate electrode 3 and the gate connecting layer 31 by CVD (chemical vapor deposition) process. After that, an oxide semiconductor film 50′ is formed over the gate insulating layer 4.

As the substrate 1, a transparent insulating substrate such as a glass substrate, for example, may be used. The gate electrode 3 and gate connecting layer 31 may be formed by depositing a conductive film on the substrate 1 by sputtering process and then patterning the conductive film by photolithographic process using a first photomask (not shown). In this example, a multilayer film with a double layer structure consisting of a TaN film (with a thickness of about 50 nm) and a W film (with a thickness of about 370 nm) that have been stacked one upon the other in this order on the substrate 1 is used as the conductive film. As this conductive film, a single-layer film of Ti, Mo, Ta, W, Cu, Al or Cr, a multilayer film or alloy film including any of these elements in combination, or a metal nitride film thereof may also be used.

The gate insulating layer 4 may be made of SiO₂, SiNₓ, SiOₓN_{y} (silicon oxynitride, where x>y), SiNₓO_{y} (silicon nitride oxide, where x>y), Al₂O₃, or Ta₂O₅. In this embodiment, a gate insulating layer 4 with a double layer structure comprised of insulating layers 4a and 4b is formed. In this example, the insulating layer 4a may be formed out of an SiNₓ film (with a thickness of about 325 nm) and the insulating layer 4b may be formed out of an SiO₂ film (with a thickness of about 50 nm).

The oxide semiconductor film 50′ may be deposited over the gate insulating layer 4 by sputtering process, for example.

The oxide semiconductor film 50′ may include In, Ga and Zn. For example, the oxide semiconductor film 50′ may include an In—Ga—Zn—O based semiconductor. The oxide semiconductor material included in the oxide semiconductor film 50′ does not have to be an In—Ga—Zn—O based semiconductor, but may also be a Zn—O based semiconductor (ZnO), an In—Zn—O based semiconductor (IZO™), a Zn—Ti—O based semiconductor (ZTO), a Cd—Ge—O based semiconductor, a Cd—Pb—O based semiconductor, CdO (cadmium oxide), an Mg—Zn—O based semiconductor, an In—Sn—Zn—O based semiconductor (such as In₂O₃—SnO₂—ZnO) or an In—Ga—Sn—O based semiconductor, for example. The thickness of the oxide semiconductor film 50′ may fall within the range of about 30 nm to about 100 nm, for example. In this example, an In—Ga—Zn—O based semiconductor film (with a thickness of approximately 50 nm) is used as the oxide semiconductor film 50′.

The In—Ga—Zn—O based semiconductor may be either amorphous or crystalline. If the In—Ga—Zn—O based semiconductor is a crystalline one, a crystalline In—Ga—Zn—O based semiconductor, of which the c axis is substantially perpendicular to the layer plane, is suitably used. The crystal structure of such an In—Ga—Zn—O based semiconductor is disclosed, for example, in Japanese Laid-Open Patent Publication No. 2012-134475, the entire disclosure of which is hereby incorporated by reference. Furthermore, the oxide semiconductor film 50′ may also be ZnO in an amorphous state, a polycrystalline state, or a microcrystalline state (which is a mixture of amorphous and polycrystalline states) to which one or multiple dopant elements selected from the group consisting of Group I, Group XIII, Group XIV, Group XV and Group XVII elements have been added, or may even be ZnO to which no dopant elements have been added at all. If an amorphous oxide semiconductor film is used as the oxide semiconductor film 50′, the semiconductor device can be fabricated at a low temperature and can achieve high mobility.

Next, as shown in FIG. 2(b), the oxide semiconductor film 50′ is patterned using a second photomask (not shown) to obtain an oxide layer 50. Thereafter, a protective layer 8b′ is deposited over the oxide layer 50. As the protective layer 8b′, an SiO₂ film (with a thickness of 150 nm, for example) may be used, for example.

Subsequently, as shown in FIG. 2(c), a resist film 111′ is formed over the protective film 8b′. When this resist film 111′ is exposed to radiation coming from the back surface of the substrate 1, the gate electrode 3 and the gate connecting layer 31 function as a mask. As a result, a resist layer 111a, 111b is obtained as shown in FIG. 2(d).

Thereafter, as shown in FIG. 2(e), the protective layer 8b′ is etched using the resist layer 111a, 111b as an etching mask. As a result, a protective layer 8b which covers a portion of the oxide layer 50 to be a channel region and a protective layer 8c which is located in the source-gate connecting portion are obtained.

Next, as shown in FIG. 3(a), the oxide layer 50 is subjected to a resistance lowering process by irradiating the substrate 1 with plasma coming from over the substrate 1. In this process step, through the plasma irradiation, a portion of the oxide layer 50 which is not covered with the protective layers 8b and 8c has its resistance lowered.

As a result of this resistance lowering process, portions of the oxide layer 50 which are not covered with the protective layer 8b have had their resistance lowered to be conductor regions 55 and 56 as shown in FIG. 3(b). Meanwhile, the rest of the oxide layer 50 that has not had its resistance lowered is left as a semiconductor region 51. The electrical resistance of those portions that have been subjected to the resistance lowering process (i.e., the low resistance portions) is lower than that of the portion that has not been subjected to the resistance lowering process (i.e., the high resistance portion).

The resistance lowering process may be plasma processing or doping a p-type dopant or an n-type dopant, for example. If a region that needs to have its resistance lowered is doped with a p-type dopant or an n-type dopant, then the dopant concentration of the conductor regions 55, 56 becomes higher than that of the semiconductor region 51. It should be noted that if a dopant is going to be implanted using a doping system, the upper insulating layer 11 could be formed over the oxide layer 50 and then the resistance lowering process could be carried out by implanting the dopant through the insulating layer 11.

As indicated by the arrows, due to diffusion of the dopant, sometimes portions of the oxide layer 50 which are located under the end portions of the protective layer 8b may also have their resistance lowered and eventually form part of the conductor regions 55 and 56. In that case, the end portions of the conductor regions 55 and 56 on the channel side will contact directly with the lower surface of the protective layer 8b.

Examples of alternative resistance lowering processes include hydrogen plasma processing using a CVD system, argon plasma processing using an etching system, and an annealing process under a reducing ambient.

Thereafter, as shown in FIG. 3(c), a source line layer including a source electrode 6s, a drain electrode 6d and a source connecting layer 32 is formed. The source line layer may be obtained by depositing a conductive film (not shown) by sputtering process on the oxide layer 50 and the protective layers 8b, 8c and then patterning the conductive film through a third photomask (not shown), for example. A hole to expose a portion of the protective layer 8c is formed in the source connecting layer 32.

The conductive film to be the source line layer may have a multilayer structure comprised of Ti, Al and Ti layers, for example. The lower Ti layer may have a thickness of about 50 nm, the Al layer may have a thickness of about 200 nm, and the upper Ti layer may have a thickness of about 100 nm.

Next, as shown in FIG. 3(d), an upper insulating layer (passivation film) 11 is formed so as to cover the source line layer and the oxide layer 50. In this embodiment, an SiO₂ film (with a thickness of 200 nm, for example) is deposited as the upper insulating layer 11. A hole is formed in a predetermined region of the upper insulating layer 11 using a fourth photomask (not shown). In this embodiment, in the source-gate connecting portion, a hole C1 which runs through the upper insulating layer 11, protective layer 8c and gate insulating layer 4 to reach the gate connecting layer 31 is cut inside the hole of the source connecting layer 32. In addition, contact holes which reach the source and drain electrodes 6s and 6d, respectively, and a hole which reaches the source connecting layer at the terminal portion are also cut by known methods.

Thereafter, as shown in FIG. 3(e), a transparent conductive film is deposited to a thickness of 100 nm, for example, on the upper insulating layer 11 and then patterned, thereby forming an upper transparent electrode 9 and an upper connecting layer 33. As the transparent conductive film, an ITO (indium tin oxide) film, an IZO film or any other suitable film may be used. Although not shown, the upper transparent electrode 9 also fills the hole of the upper insulating layer and is connected to a predetermined potential. Furthermore, in the source-gate connecting portion, the transparent connecting layer 33 contacts with the gate connecting layer 31 inside the hole C1 that has been cut through the upper insulating layer 11, the protective layer 8c and the gate insulating layer 4. In this manner, a semiconductor device (TFT substrate) 100A is completed.

As can be seen from the foregoing description, according to this embodiment, an extended line to connect together respective portions of the gate line layer and source line layer can be formed by patterning a transparent conductive film. In addition, since the oxide layer 50 is not present under the source line layer (e.g., the source connecting layer 32 in this example), a contact hole that reaches the gate line layer (e.g., the gate connecting layer 31 in this example) can be cut easily. In this case, since the area (i.e., the layout area) assigned to a contact can be reduced with the diameter of the contact hole reduced, a semiconductor device of even higher definition can be fabricated. Consequently, a thin-film transistor array in which not only pixel switching TFTs but also a peripheral circuit and a pixel circuit to be used in a medium to small sized high definition display are integrated together can be fabricated easily.

Thereafter, a counter substrate is provided and the counter substrate and the TFT substrate 100A are fixed with a liquid crystal layer interposed between them. In this manner, a liquid crystal display device is completed.

According to this method, the following advantages can be achieved.

Specifically, since a self-alignment process using the back surface exposure is adopted to pattern the protective layers 8b and 8c, the number of masks to use can be reduced. In addition, there is no need to position the protective layers 8b and 8c with respect to the gate line layer and the source line layer any longer. Furthermore, according to the method described above, the position of the boundary between the conductor region and non-conductor region of the oxide semiconductor film 50′ is controlled using the protective layers 8b and 8c that have been patterned in this manner. That is why the processing of selectively lowering the resistance of the oxide semiconductor film 50′ (i.e., turning a selected portion of the oxide semiconductor film 50′ into a conductor) can be controlled easily, which leads to an increase in yield.

In the example illustrated in FIGS. 2 and 3, a portion of the oxide layer 50 to be a channel (i.e., its channel portion) is located over the gate electrode 3 when viewed along a normal to the substrate 1. That is why by exposing the resist film 111′ to radiation using the gate electrode 3 as a mask to say the least, the protective layer 8b can be left over the channel portion with more certainty. This protective layer 8b not only defines the semiconductor region 51 of the oxide semiconductor layer 50 but also functions as a so-called “etch stop (ES)” as well. If the channel portion is covered with the protective layer 8b, the damage to be done on the channel portion during the process step can be cut down, and deterioration on the back channel side can be suppressed. As a result, dispersion in TFT characteristic can be reduced and the performance of the TFT can be enhanced.

In addition, the gate line layer and source line layer which can be patterned into lines can be formed separately from each other, which is also beneficial. Furthermore, even if the source line layer and the oxide layer, for example, are not patterned simultaneously, the number of masks to use can also be reduced. On top of that, as will be described later with respect to other embodiments, this method is also applicable to a TFT with a bottom contact structure.

Although the resistance lowering process (such as plasma processing) is supposed to be performed according to the method described above using the protective layer 8b as a mask, the resist layer 111a may be formed by back surface exposure process without forming the protective layer 8′ and the resistance lowering process may be carried out using the resist layer 111a as a mask.

The upper insulating layer 11 does not have to be an SiO₂ film but may also be an SiN film or any other insulating film. Optionally, the upper insulating layer 11 may have a multilayer structure.

The semiconductor device 100A of this embodiment may be used in a fringe field switching (FFS) mode liquid crystal display device, for example.

FIG. 4 is a cross-sectional view illustrating an FFS mode liquid crystal display device 500 which uses the semiconductor device 100A. In this case, the conductor region 55 of the oxide layer 50 is used as a pixel electrode to which a display signal voltage is applied, and the upper transparent electrode 9 is used as a common electrode (to which either a common voltage or a counter voltage is applied). At least one slit is cut through the upper transparent electrode 9. An FFS mode liquid crystal display device 500 with such a configuration is disclosed in Japanese Laid-Open Patent Publication No. 2011-53443, for example, the entire disclosure of which is hereby incorporated by reference.

This liquid crystal display device 500 includes a TFT substrate 100A, a counter substrate 200, and a liquid crystal layer 50 interposed between the TFT substrate 100A and the counter substrate 200. In this liquid crystal display device 500, no counter electrode such as a transparent electrode of ITO, for example, is arranged on the surface of the counter substrate 200 to face the liquid crystal layer 50. Instead, a display operation is carried out by controlling the alignments of liquid crystal molecules in the liquid crystal layer 50 with a lateral electric field which has been generated by the pixel and common electrodes that have been formed on the TFT substrate 100A.

### Modified Example of Embodiment 1

In the semiconductor device 100A shown in FIG. 1, the upper insulating layer 11 may be a reducing insulating layer with the property of reducing an oxide semiconductor included in the semiconductor region 51 of the oxide layer 50. Alternatively, the upper insulating layer 11 may include a reducing insulating layer which contacts with the oxide layer 50.

When in contact with an oxide semiconductor film, the reducing insulating layer has the function of lowering its electrical resistance. Thus, by using a reducing insulating layer, a portion of the oxide layer 50 can turn into a conductor. That is why since there is no need to carry out the resistance lowering process such as plasma processing or doping (see FIG. 3(a)) on the oxide semiconductor film, the manufacturing process can be simplified.

Next, a reducing insulating layer according to this embodiment will be described in further detail with reference to FIG. 12.

FIG. 12(a) is a graph showing a gate voltage (Vg)-drain current (Id) curve of an oxide semiconductor TFT having a configuration in which an oxide insulating layer (of SiO₂, for example) has been formed so as to contact with the entire lower surface of an oxide semiconductor layer (active layer). On the other hand, FIG. 12(b) is a graph showing a gate voltage (Vg)-drain current (Id) curve of an oxide semiconductor TFT having a configuration in which a reducing insulating layer (of SiNₓ, for example) has been formed so as to contact with the entire lower surface of an oxide semiconductor layer (active layer).

As can be seen from FIG. 12(a), an oxide semiconductor TFT in which an oxide insulating layer contacts directly with an oxide semiconductor layer has a good TFT characteristic.

On the other hand, as can be seen from FIG. 12(b), an oxide semiconductor TFT in which a reducing insulating layer contacts directly with an oxide semiconductor layer does not have a TFT characteristic, and the oxide semiconductor layer is turned into a conductor by the reducing insulating layer. This is probably because the reducing insulating layer will include a lot of hydrogen and will reduce the oxide semiconductor and lower the resistance of the oxide semiconductor layer by contacting with the oxide semiconductor layer.

The results shown in FIG. 12 reveal that if the reducing insulating layer is arranged so as to contact with the oxide semiconductor layer, a portion of the oxide semiconductor layer which contacts with the reducing insulating layer will be a low-resistance region with a lower electrical resistance than the other portion and will no longer function as an active layer. That is why if such a reducing insulating layer is formed as part or all of the upper insulating layer 11 so as to directly contact with only a portion of the oxide layer (oxide semiconductor layer) 50, the oxide layer 50 can have its resistance lowered locally and the conductor region 55 can be obtained. As a result, there is no need to perform any special resistance lowering process (such as a hydrogen plasma treatment) any longer, and the manufacturing process can be further simplified.

FIG. 13 illustrates an exemplary TFT substrate to be obtained by using a reducing insulating layer as the upper insulating layer 11 and by performing no special resistance lowering process.

The reducing insulating layer may be made of SiNₓ, for example. The reducing insulating layer may be formed at a substrate temperature of about 100° C. to about 250° C. (e.g., at 220° C.) and with the flow rates of SiH₄ and NH₃ gases adjusted so that the flow rate ratio (in sccm) of an SiH₄ and NH₃ mixed gas (i.e., the ratio of the flow rate of SiH₄ to the flow rate of NH₃) falls within the range of 4 to 20.

### Embodiment 2

Hereinafter, a semiconductor device as a second embodiment of the present invention will be described with reference to the accompanying drawings.

FIG. 5(a) is a schematic plan view illustrating a TFT substrate 100B according to this second embodiment. FIG. 5(b) is a schematic cross-sectional view of the semiconductor device (TFT substrate) 100B as viewed on the plane A-A′ shown in FIG. 5(a). And FIG. 5(c) is a cross-sectional view of the semiconductor device (TFT substrate) 100B as viewed on the plane C-C′.

In this TFT substrate 100B, an oxide layer 50 has been formed over a source line layer including the source electrode 6s, the drain electrode 6d and the source connecting layer 32, which is a major difference from the TFT substrate 100A shown in FIG. 1.

In this TFT substrate 100B, the oxide layer 50 has been formed to contact with the upper surface of the source and drain electrodes 6s and 6d. The oxide layer 50 includes a semiconductor region 51 (including a channel region) and a conductor region 55. The conductor region 55 contacts with a side surface of the drain electrode 6d. The protective layer 8b, 8c has been formed so as to overlap with at least one of a source line layer and a gate line layer when viewed along a normal to the substrate 1. The protective layer 8b is arranged to cover the upper surface of the semiconductor region 51. In the example illustrated in FIG. 5, an end portion of the semiconductor region 51 on the source side is located between the source electrode 6s and the protective layer 8b, and no conductor region has been formed in contact with that end portion of the semiconductor region 51 on the source side. In the other respects, this configuration is the same as the one shown in FIG. 1.

According to this embodiment, a mask (e.g., the protective layer 8b in this embodiment) for use to perform a resistance lowering process on the oxide layer 50 is formed by self-alignment process using exposing radiation coming from under the back surface of the substrate 1 (i.e., by back surface exposure process). Although the back surface exposure process is supposed to be carried out using the gate electrode 3 as a mask in the embodiment described above (shown in FIGS. 2 and 3), not only the gate electrode 3 but also the source and drain electrodes 6s and 6d serve as a mask in this embodiment during the exposure process. After that, using the resistance lowering processing mask (e.g., the protective layer 8 in this embodiment) that has been obtained through the back surface exposure, a conductor region 55 is defined in the oxide layer 50. As a result, when viewed along a normal to the substrate 1, a portion of the oxide layer 50 which does not overlap with any of the gate electrode 3 and source and drain electrodes 6s and 6d has its resistance lowered to be the conductor region 55. On the other hand, the rest of the oxide layer 50 that has not had its resistance lowered becomes a semiconductor region 51.

If the TFT substrate 100B is fabricated by adopting such a self-alignment process, the end portion of the protective layer 8b will be substantially aligned with that of the gate electrode 3, source electrode 6s or drain electrode 6d when viewed along a normal to the substrate 1. In addition, at least a portion of the boundary between the semiconductor region 51 and the conductor region 55 will also be substantially aligned with the end portion of the protective layer 8b and the end portion of the drain electrode 6d. As in the embodiment described above, those end portions are also regarded as being “substantially aligned with” each other even if that end portion of the layer to be etched or the region to have its resistance lowered is located inside or outside of that of the layer to be a mask due to the etching process condition or diffusion of the dopants in the conductor region.

In this manner, according to this embodiment, the semiconductor region 51 is arranged inside of the profile of a region which overlaps with at least one of the gate electrode 3 and source and drain electrodes 6s and 6d. It should be noted that if the semiconductor region 51 is “arranged inside of” the profile of such a region, the end portion of the semiconductor region 51 may not only be located inside of, but also be aligned with, that of any of these electrodes.

In the source-gate connecting portion of this TFT substrate 100B, the protective layer 8c is located over the source connecting layer 32, which is a major difference from the structure of the source-gate connecting portion of the TFT substrate 100A. The protective layer 8c has also been patterned by performing a back surface exposure process using the source connecting layer 32 and the gate connecting layer 31 as a mask.

In the TFT substrate 100B of this embodiment, a storage capacitor is also formed by the conductor region 55, the upper transparent electrode 9 and the insulating layer between them as in the embodiment described above, thus achieving a high aperture ratio as well. In addition, according to this embodiment, the position of the boundary between the conductor region to be defined by the resistance lowering process and the semiconductor region in the oxide layer 50 can also be controlled by self-alignment process using the back surface exposure. Consequently, the number of masks to use can be reduced, the manufacturing process can be simplified, and the yield can be increased.

(Method for Fabricating TFT Substrate 100B)

Just like the TFT substrate 100A, the TFT substrate 100B of this embodiment is also applicable to an FFS mode liquid crystal display device (see FIG. 4), for example.

Hereinafter, an exemplary method for fabricating the TFT substrate 100B will be described with reference to FIGS. 6(a) through 6(e) and FIGS. 7(a) through 7(d).

First of all, as shown in FIG. 6(a), a gate line layer including a gate electrode 3 and a gate connecting layer 31 is formed on the substrate 1, and then a gate insulating layer 4 is formed over the gate line layer. Thereafter, a source line layer including a source electrode 6s, a drain electrode 6d and a source connecting layer 32 is formed on the gate insulating layer 4. The gate line layer, gate insulating layer 4 and source line layer may be made of the same materials, may have the same thicknesses, and may be formed in the same way as what has already been described for the first embodiment.

Subsequently, as shown in FIG. 6(b), an oxide semiconductor film (not shown) is deposited over the source line layer and the gate insulating layer 4 and patterned, thereby obtaining an oxide layer 50. Next, a protective film 8′ is deposited over the oxide layer 50. The oxide layer 50 and the protective film 8′ may be made of the same materials, may have the same thicknesses, and may be formed in the same way as what has already been described for the first embodiment.

Thereafter, as shown in FIG. 6(c), a resist film 112′ is formed on the protective film 8′. And the resist film 112′ is exposed to radiation coming from the back surface of the substrate 1. In this process step, the gate electrode 3, source electrode 6s, drain electrode 6d, gate connecting layer 31 and source connecting layer 32 serve as a mask. As a result, the resist film 112′ is patterned so as to be self-aligned and resist layers 112a and 112b are formed as shown in FIG. 6(d). When viewed along a normal to the substrate 1, the resist layer 112a is located so as to overlap with the gate electrode 3, source electrode 6s and drain electrode 6d, and the resist layer 112b is located so as to overlap with the gate connecting layer 31 and source connecting layer 32.

Subsequently, as shown in FIG. 7(a), the protective film 8′ is patterned using the resist layers 112a and 112b as a mask, thereby obtaining a protective layer 8b which covers a portion of the oxide layer 50 to be a channel and a protective layer 8c located in the source-gate connecting portion. The protective layer 8c is provided on the source connecting layer 32 and inside the hole of the source connecting layer 32.

Thereafter, a portion of the oxide layer 50 is subjected to a resistance lowering process from over the substrate 1. The resistance lowering process may be performed in the same way as already described for the first embodiment. As a result, as shown in FIG. 7(b), a portion of the oxide layer 50 which is not covered with the protective layers 8b and 8c has its resistance lowered to turn into a conductor region 55. On the other hand, the rest of the oxide layer 50 that has not had its resistance lowered becomes a semiconductor region 51. It should be noted that as indicated by the arrows, a portion of the oxide layer 50 which is located under an end portion of the protective layer 8b on the drain side may also turn into a conductor due to diffusion of dopants. In that case, a portion of the conductor region 55 will also be defined between the drain electrode 6d and the protective layer 8b.

Subsequently, as shown in FIG. 7(c), an upper insulating layer (passivation film) 11 is deposited over the oxide layer 50 and the protective layers 8b and 8c. Next, a hole C2 which runs through the upper insulating layer 11, protective layer 8c and gate insulating layer 4 and reaches the gate connecting layer 31 is cut inside of the hole of the source connecting layer 32. The upper insulating layer 11 may be made of the same material, may have the same thickness, and may be formed in the same way as what has already been described for the first embodiment.

Thereafter, as shown in FIG. 7(d), a transparent conductive film (not shown) is deposited on the upper insulating layer 11 and patterned, thereby forming an upper transparent electrode 9 and also forming a transparent connecting layer 33 which contacts with the gate insulating layer 31 inside the hole C2 that has been cut through the source-gate connecting portion. The transparent conductive film may be made of the same material, may have the same thickness, and may be formed in the same way as what has already been described for the first embodiment. In this manner, a TFT substrate 100B is completed.

Optionally, according to this embodiment, a resistance lowering process may also be performed on the oxide layer 50 using the resist layer 112a (see FIG. 6(d)) as a mask without forming the protective film 8′.

Furthermore, a reducing insulating layer may also be used as the upper insulating layer 11. In that case, a special resistance lowering process for turning a portion of the oxide layer 50 into a conductor can be omitted and the TFT substrate 100B can be obtained by a simpler process.

### Embodiment 3

Hereinafter, a semiconductor device as a third embodiment of the present invention will be described with reference to the accompanying drawings.

FIG. 8(a) is a schematic plan view illustrating a TFT substrate 100C according to this third embodiment. FIG. 8(b) is a schematic cross-sectional view of the semiconductor device (TFT substrate) 1000 as viewed on the plane shown in FIG. 8(a). And FIG. 8(c) is a cross-sectional view of the semiconductor device (TFT substrate) 100C as viewed on the plane C-C′.

This TFT substrate 100C includes a lower transparent electrode 2 which is arranged under the oxide layer 50 (i.e., closer to the substrate 1 instead of the upper transparent electrode, which is a major difference from the TFT substrate 100B of the embodiment described above (see FIG. 5).

This TFT substrate 100C includes a substrate 1, a gate electrode 3 and a lower transparent electrode 2 which have been formed on the substrate 1, insulating layers 4a and 4b which have been deposited over the gate electrode 3 and the lower transparent electrode 2, and an oxide layer 50 which has been formed on the insulating layers 4a and 4b. The insulating layers 4a and 4b function as a gate insulating layer 4. Also, in this example, another insulating layer 4c has been formed between the lower transparent electrode 2 and the gate electrode 3. The lower transparent electrode 2 and the gate electrode 3 just need to be arranged closer to the substrate 1 than the oxide layer 50 is. Thus, the lower transparent electrode 2 may be located over the gate electrode 3. Furthermore, in the source-gate connecting portion, the gate connecting layer 31 is connected to the source connecting layer 32 inside a hole formed in the gate insulating layer 4. The source connecting layer 32 is covered with a protective layer 8c. In the other respects, this configuration may be the same as that of the TFT substrate 100B.

In this TFT substrate 100C, a storage capacitor is formed by making at least a portion of the lower transparent electrode 2 overlap with the conductor region 55 with the gate insulating layer 4 interposed between them. The storage capacitor that this TFT substrate 100C has is transparent (i.e., can transmit visible light), and does not decrease the aperture ratio. That is why as in the other embodiments described above, this TFT substrate 100C can also have a higher aperture ratio than conventional ones. In addition, since the aperture ratio is not decreased by the storage capacitor, the capacitance value of the storage capacitor (i.e., the area of the storage capacitor) can be increased as needed.

According to this embodiment, by performing an exposure process from under the back surface of the substrate 1, a protective layer 8b (or resist layer) to function as a mask when the resistance lowering process is performed on the oxide layer 50 can be formed as in the embodiments described above. Since such a self-alignment process is used, the number of manufacturing process steps and the manufacturing cost can be cut down, and the yield can be increased.

Hereinafter, a liquid crystal display device including such a TFT substrate 100C will be described with reference to FIG. 9. Specifically, FIGS. 9(a) to 9(c) are schematic cross-sectional views of a liquid crystal display device including the TFT substrate 100C. In FIGS. 9(a) to 9(c), the dotted arrows indicate the directions of an electric field.

As shown in FIG. 9(a), the TFT substrate 100C may be used in an FFS mode liquid crystal display device 500′, for example. In this case, the lower transparent electrode 2 is used as a common electrode (to which either a common voltage or a counter voltage is applied) and the conductor region 55 that forms the upper layer is used as a pixel electrode (to which a display signal voltage is applied). At least one slit is cut through the conductor region 55. A more detailed configuration and principle of display of an FFS mode liquid crystal display device have already been described with reference to FIG. 4, and description thereof will be omitted herein.

In this TFT substrate 100C, the lower transparent electrode (common electrode) 2 is located closer to the substrate 1 than the conductor region 55 that is the upper transparent electrode (pixel electrode). That is why this TFT substrate 100C can be used in not only the FFS mode liquid crystal display device 500′ but also liquid crystal display devices in any of various other liquid crystal modes as well.

For example, this TFT substrate 100C may be used in a vertical electric field mode liquid crystal display device 600 as shown in FIG. 9(b) in which a counter electrode 27 is arranged on one surface of the counter substrate 200 to face the liquid crystal layer and which conducts a display operation by controlling the alignments of liquid crystal molecules in the liquid crystal layer 150 with a vertical electric field generated by the counter electrode 27 and the conductor region (pixel electrode) 55. In that case, a plurality of slits does not have to be cut through the conductor region 55.

Furthermore, the TFT substrate 100C may also be used in a vertical/lateral electric field mode liquid crystal display device 700 as shown in FIG. 9(c) in which a counter electrode 27 is arranged on one surface of the counter substrate 200 to face the liquid crystal layer and a plurality of slits are cut through the conductor region (pixel electrode) 55 and which conducts a display operation by controlling the alignments of liquid crystal molecules in the liquid crystal layer 150 with a lateral electric field generated by the conductor region (pixel electrode) 55 and the lower transparent electrode (common electrode) 2 and with a vertical electric field generated by the conductor region (pixel electrode) 55 and the counter electrode 27. Such a liquid crystal display device 700 is disclosed in PCT International Application Publication No. 2012/053415, for example.

(Method for Fabricating TFT Substrate 100C)

Hereinafter, a method for fabricating the TFT substrate 100C will be described.

FIGS. 10(a) through 10(f) are schematic cross-sectional views illustrating an exemplary method for fabricating the TFT substrate 100C.

First of all, as shown in FIG. 10(a), a lower transparent electrode 2 is formed on a substrate 1. As the substrate 1, a transparent insulating substrate such as a glass substrate, for example, may be used. The lower transparent electrode 2 may be formed by depositing a transparent conductive film and then patterning it through the first photomask. The lower transparent electrode 2 may be made of ITO, for example, and may have a thickness of about 100 nm.

Next, as shown in FIG. 10(b), an insulating layer 4c is deposited over the lower transparent electrode 2 by CVD process or any other suitable method. After that, a gate electrode 3 and a gate connecting layer 31 are formed on the insulating layer 4c.

In order to prevent the semiconductor property of the semiconductor region 51 from deteriorating, the insulating layer 4c is suitably made of either SiO₂ or SiOₓN_{y} (silicon oxynitride, where x>y). In this embodiment, the insulating layer 4c may be made of SiNₓ, for example, and may have a thickness of about 100 nm.

The gate electrode 3 and the gate connecting layer may be formed by depositing a conductive film on the insulating layer 4c by sputtering process and then patterning the conductive film by photolithographic process using the second photomask. It should be noted that when viewed along a normal to the substrate 1, the gate electrode 3 and the lower transparent electrode 2 are arranged so as not to overlap with each other. In this example, a multilayer film with a double layer structure consisting of a TaN film (with a thickness of about 50 nm) and a W film (with a thickness of about 370 nm) that have been stacked one upon the other in this order on the substrate 1 is used as the conductive film. As this conductive film, a single-layer film of Ti, Mo, Ta, W, Cu, Al or Cr, a multilayer film or alloy film including any of these elements in combination, or a metal nitride film thereof may also be used.

Next, as shown in FIG. 10(c), insulating layers 4a and 4b are formed by CVD process, for example, to cover the gate electrode 3. In this example, the insulating layer 4a is formed out of an SiNₓ film (with a thickness of about 225 nm) and the insulating layer 4b is formed out of an SiO₂ film (with a thickness of about 50 nm). Thereafter, a hole that exposes the gate connecting layer 31 is formed in the insulating layers 4a and 4b (that form the gate insulating layer 4) using the third photomask.

By providing such a portion to contact with the gate line layer in this manner, not only pixel switching TFTs but also a thin-film transistor array in which peripheral circuits and a pixel circuit are integrated together as required by a medium to small sized high definition display can be fabricated easily.

Subsequently, as shown in FIG. 10(d), a source line layer including a source electrode 6s, a drain electrode 6d and a source connecting layer 32 is formed over the gate insulating layer 4, and then an oxide semiconductor film 50′ is formed.

The source electrode 6s, drain electrode 6d and source connecting layer 32 may be formed by depositing a conductive film (not shown) by sputtering process and then patterning the conductive film using the fourth photomask, for example. The conductive film may have a multilayer structure consisting of Ti, Al and Ti layers, for example. The lower Ti layer may have a thickness of about 50 nm, the Al layer may have a thickness of about 200 nm, and the upper Ti layer may have a thickness of about 100 nm. The source connecting layer 32 is arranged so as to contact with the gate connecting layer 31 inside the hole formed in the gate insulating layer 4.

The oxide semiconductor film 50′ may be formed by sputtering process, for example. In this embodiment, an In—Ga—Zn—O based semiconductor film (with a thickness of about 50 nm) is used as the oxide semiconductor film 50′.

Thereafter, as shown in FIG. 10(e), the oxide semiconductor film 50′ is patterned using the fifth photomask, thereby obtaining an oxide layer 50. Subsequently, a protective film (not shown) is deposited on the oxide layer 50 and then patterned to form protective layers 8b and 8c, which may be made of an oxide (such as SiO₂) and may have a thickness of about 150 nm. In the same way as the method that has already been described with reference to FIGS. 6(c) through 6(e) and FIG. 7(a), the protective film can be patterned so as to be self-aligned by performing a back surface exposure process using the source and gate line layers.

Thereafter, as shown in FIG. 10(f), a portion of the oxide layer 50 is subjected to the resistance lowering process. As a result, the portion of the oxide layer 50 that is not covered with the protective layer 8b has its resistance lowered to be a conductor region 55. Meanwhile, the rest of the oxide layer 50 that is covered with the protective layer 8b and that has not had its resistance lowered is left as the semiconductor region 51. The electrical resistance of the portion that has been subjected to the resistance lowering process (i.e., the low resistance portion) is lower than that of the portion that has not been subjected to the resistance lowering process (i.e., the high resistance portion). The resistance lowering process may be carried out in the same way as already described for the first embodiment.

### Modified Example of Embodiment 3

In this embodiment, the lower transparent electrode 2 is arranged over the gate electrode 3. Such a TFT substrate may be fabricated in the following manner, for example.

FIGS. 11(a) through 11(f) are schematic cross-sectional views illustrating an exemplary series of manufacturing process steps to fabricate a TFT substrate according to this modified example. In the following description, the materials and thicknesses of the respective films and layers and the methods of making them may be the same as what has already been described with reference to FIG. 10 and will not be described all over again.

First of all, as shown in FIG. 11(a), a gate electrode 3 and a gate connecting layer 31 are formed on a substrate 1.

Next, as shown in FIG. 11(b), an insulating layer 4c is deposited over the gate electrode 3 and gate connecting layer 31 by CVD process, for example, and then a lower transparent electrode 2 is formed on the insulating layer 4c.

Subsequently, as shown in FIG. 11(c), insulating layers 4a and 4b are deposited over the lower transparent electrode 2. After that, a hole that exposes the gate connecting layer 31 is formed in the insulating layers 4a and 4b (that form a gate insulating layer 4) and the insulating layer 4c.

By providing such a portion to contact with the gate line layer in this manner, a thin-film transistor array in which not only pixel switching TFTs but also a peripheral circuit and a pixel circuit are integrated together can be fabricated easily.

Next, as shown in FIG. 11(d), a source line layer including a source electrode 6s, a drain electrode 6d and source connecting layer 32 is formed on the gate insulating layer 4 and then an oxide semiconductor film 50′ is formed. The source connecting layer 32 is arranged so as to contact with the gate connecting layer 31 inside a hole formed in the gate insulating layer 4.

Thereafter, as shown in FIG. 11(e), an oxide layer 50 is obtained by patterning the oxide semiconductor film 50′. Then, a protective film (not shown) is formed on the oxide layer 50 and then patterned by performing a self-alignment process using a back surface exposure process, thereby obtaining protective layers 8b and 8c.

Subsequently, as shown in FIG. 11(f), a portion of the oxide layer 50 is subjected to a resistance lowering process, thereby defining a conductor region 55 and a semiconductor region 51 in the oxide layer 50.

Optionally, in this embodiment, the resistance lowering process on the oxide layer 50 may also be performed in the process step shown in FIGS. 10(e) and 11(e) by using, as a mask, a resist layer to be obtained through the back surface exposure process without forming the protective film (to be the protective layer 8b).

### INDUSTRIAL APPLICABILITY

Embodiments of the present invention are applicable broadly to various types of devices that use a thin-film transistor. Examples of such devices include circuit boards such as an active-matrix substrate, display devices such as a liquid crystal display, an organic electroluminescence (EL) display, and an inorganic electroluminescence display, image capture devices such as an image sensor, and electronic devices such as an image input device and a fingerprint scanner.

### REFERENCE SIGNS LIST

1 substrate
2 lower transparent electrode
3 gate electrode
4 gate insulating layer
4a, 4b, 4c insulating layer
6s source electrode
6d drain electrode
8b, 8c protective layer
9 upper transparent electrode
11 upper insulating layer
31 gate connecting layer
32 source connecting layer
33 transparent connecting layer
50 oxide layer
55, 56 conductor region
51 semiconductor region
150 liquid crystal layer
100, 100A, 100B, 100C semiconductor device (TFT substrate)
200 counter substrate
500, 500′, 600, 700 liquid crystal display device

1-18. (canceled)

19. A semiconductor device comprising:
a substrate;
a gate electrode formed on the substrate;
a gate insulating layer formed over the gate electrode;
an oxide layer which is formed on the gate insulating layer and which includes a semiconductor region and a first conductor region that contacts with the semiconductor region and where the semiconductor region at least partially overlaps with the gate electrode with the gate insulating layer interposed between them;
a protective layer covering the upper surface of the semiconductor region;
source and drain electrodes electrically connected to the semiconductor region; and
a transparent electrode arranged so as to overlap at least partially with the first conductor region with a dielectric layer interposed between them,
wherein the drain electrode contacts with the first conductor region, and
when viewed along a normal to the substrate, an end portion of the protective layer is substantially aligned with an end portion of the drain electrode, an end portion of the source electrode or an end portion of the gate electrode, and at least a portion of a boundary between the semiconductor region and the first conductor region is substantially aligned with the end portion of the protective layer.

20. The semiconductor device of claim 19, wherein when viewed along a normal to the substrate, the semiconductor region is arranged inside of a profile of the gate electrode.

21. The semiconductor device of claim 19, wherein the oxide layer further includes a second conductor region located on the other side of the semiconductor region opposite from the first conductor region,
the drain electrode contacts with an upper surface of the first conductor region of the oxide layer and the source electrode contacts with an upper surface of the second conductor region of the oxide layer,
the transparent electrode is an upper transparent electrode arranged over the oxide layer with the dielectric layer interposed between them, and
when viewed along a normal to the substrate, the end portion of the protective layer is substantially aligned with the end portion of the gate electrode, and at least a portion of boundaries between the semiconductor region and the first and second conductor regions is substantially aligned with the end portion of the protective layer.

22. The semiconductor device of claim 19, wherein when viewed along a normal to the substrate, the semiconductor region is arranged inside of a profile of a region which overlaps with at least one of the gate, source and drain electrodes.

23. The semiconductor device of claim 19, wherein the source and drain electrodes are formed between the gate insulating layer and the oxide layer,
the semiconductor region of the oxide layer contacts with respective upper surfaces of the source and drain electrodes, and
when viewed along a normal to the substrate, at least a portion of the boundary between the semiconductor region and the first conductor region is substantially aligned with the end portion of the drain electrode.

24. The semiconductor device of claim 23, wherein the transparent electrode is an upper transparent electrode arranged over the oxide layer with the dielectric layer interposed between them.

25. The semiconductor device of claim 22, wherein the transparent electrode is a lower transparent electrode arranged between the oxide layer and the substrate and the dielectric layer includes at least a portion of the gate insulating layer.

26. The semiconductor device of claim 21, further comprising a source-drain connecting portion, the source-drain connecting portion includes:
a gate connecting layer formed out of the same conductive film as the gate electrode;
a source connecting layer formed out of the same conductive film as the source electrode; and
a transparent connecting layer formed out of the same transparent conductive film as the upper transparent electrode,
wherein the source connecting layer and the gate connecting layer are electrically connected together via the transparent connecting layer.

27. The semiconductor device of claim 25, further comprising a source-drain connecting portion, the source-drain connecting portion includes:
a gate connecting layer formed out of the same conductive film as the gate electrode; and
a source connecting layer formed out of the same conductive film as the source electrode,
wherein the source connecting layer contacts with the gate connecting layer inside a hole formed in the gate insulating layer.

28. The semiconductor device of claim 19, wherein the oxide layer includes In, Ga and Zn.

29. A method for fabricating a semiconductor device, the method comprising the steps of:
(A) providing a substrate having a gate electrode and a gate insulating layer formed thereon;
(B) forming an oxide semiconductor layer over the gate insulating layer;
(C) forming a resistance-lowering-processing mask on the oxide semiconductor layer so as to cover a portion of the oxide semiconductor layer, the portion being located over the gate electrode, the step (C) including the steps of:
(C1) forming a resist film on the oxide semiconductor layer, and
(C2) exposing the resist film to radiation from an opposite side of the surface of the substrate using the gate electrode as a mask, thereby forming a resist layer; and
(D) lowering the resistance of a portion of the oxide semiconductor layer which is not covered with the resistance-lowering-processing mask to define a first conductor region, and turning the rest of the oxide semiconductor layer which has not had its resistance lowered into a semiconductor region, thereby forming an oxide layer including the semiconductor region and the first conductor region.

30. The method of claim 29, further comprising the steps of:
(E) forming source and drain electrodes so that the source and drain electrodes contact with an upper surface of the oxide layer; and
(F) forming a dielectric layer over the oxide layer and then forming an upper transparent electrode so that the upper transparent electrode overlaps with at least a portion of the first conductor region with the dielectric layer interposed between them.

31. The method of claim 29, wherein the step (C) includes the step of forming a protective film on the oxide semiconductor layer before the step (C1),
the step (C2) includes forming the resist layer on the protective film, and
the step (C) further includes the step of patterning the protective film using the resist layer as a mask, thereby forming a protective layer as the resistance-lowering-processing mask, after the step (C2).

32. A method for fabricating a semiconductor device, the method comprising the steps of:
(a) providing a substrate having a gate electrode and a gate insulating layer formed thereon;
(b) forming source and drain electrodes on the gate insulating layer;
(c) forming an oxide semiconductor layer covering the source and drain electrodes;
(d) forming a resistance-lowering-processing mask on the oxide semiconductor layer so as to cover at least a portion of the oxide semiconductor layer, the portion being located over the gate electrode, the step (d) including the steps of:
(d1) forming a resist film on the oxide semiconductor layer, and
(d2) exposing the resist film to radiation from an opposite side of the surface of the substrate using the gate electrode as a mask, thereby forming a resist layer; and
(e) lowering the resistance of a portion of the oxide semiconductor layer which is not covered with the resistance-lowering-processing mask to define a first conductor region, and turning the rest of the oxide semiconductor layer which has not had its resistance lowered into a semiconductor region, thereby forming an oxide layer including the semiconductor region and the first conductor region.

33. The method of claim 32, further comprising the step (f) of forming a dielectric layer so that the dielectric layer contacts with an upper surface of the oxide layer and then forming an upper transparent electrode so that the upper transparent electrode overlaps with at least a portion of the first conductor region with the dielectric layer interposed between them.

34. The method of claim 32, further comprising the step of forming a lower transparent electrode on the substrate before the step (b),
wherein in the step (e), the first conductor region is arranged so as to overlap with the lower transparent electrode with at least a portion of the gate insulating layer interposed between them.

35. The method of claim 32, wherein the step (d) includes forming a protective film on the oxide semiconductor layer before the step (d1),
the step (d2) includes forming the resist layer on the protective film, and
the method further includes the step of patterning the protective film using the resist layer as a mask to form a protective layer as the resistance-lowering-processing mask after the step (d2).

36. The method of claim 29, wherein the oxide semiconductor layer includes In, Ga and Zn.

37. The semiconductor device of claim 23, wherein the transparent electrode is a lower transparent electrode arranged between the oxide layer and the substrate and the dielectric layer includes at least a portion of the gate insulating layer.

38. The semiconductor device of claim 24, further comprising a source-drain connecting portion, the source-drain connecting portion includes:
a gate connecting layer formed out of the same conductive film as the gate electrode;
a source connecting layer formed out of the same conductive film as the source electrode; and
a transparent connecting layer formed out of the same transparent conductive film as the upper transparent electrode,
wherein the source connecting layer and the gate connecting layer are electrically connected together via the transparent connecting layer.
